(19) United States
(12) Patent Application Publication
(10) Pub. No.: US 2015/0214242 A1
(43) Pub. Date: Jul. 30, 2015

(54) VERTICAL NON-VOLATILE MEMORY DEVICES AND METHODS OF MANUFACTURING THE SAME

(71) Applicant: Sun-Yeong Lee, Hwaseong-si (KR)

(72) Inventor: Sun-Yeong Lee, Hwaseong-si (KR)

(21) Appl. No.: 14/464,727

(22) Filed: Aug. 21, 2014

(30) Foreign Application Priority Data
Jan. 27, 2014 (KR) 10-2014-0009363

(51) Int. Cl. H01L 27/115

(52) U.S. Cl. CPC H01L 27/11582; H01L 27/11556; H01L 27/11519; H01L 27/11565

(57) ABSTRACT

A vertical non-volatile memory device includes gate electrodes stacked in a first region of a substrate in a third direction perpendicular to a top surface of the substrate including the first region and a second region surrounding the first region, a channel extending in the third direction through the gate electrodes, conductive pads extending from the gate electrodes, respectively, in a first direction parallel to the top surface of the substrate in the second region, insulation pads extending from the gate electrodes and the conductive pads, respectively, in a second direction perpendicular to the first direction in the second region, contact plugs electrically connected to the conductive pads, respectively, and a first reference structure under at least one of the insulation pads in the second region.

### CROSS-REFERENCE TO RELATED APPLICATION

This application claims priority under 35 U.S.C. §119 to Korean Patent Application No. 10-2014-0009363, filed on Jan. 27, 2014 in the Korean Intellectual Property Office (KIPO), the contents of which are incorporated by reference herein in their entirety.

### BACKGROUND

Vertical non-volatile memory devices have been developed that exhibit increased integration density as compared to conventional horizontal non-volatile memory devices. These vertical non-volatile memory devices may include a plurality of word line pads that are arranged in a staircase shape, and contact plugs may be formed on each of the word line pads that electrically connect the word line pads to upper wiring structures. The contact plugs extend vertically through the device structure to directly contact respective ones of the word line pads.

### SUMMARY

Example embodiments provide vertical non-volatile memory devices that exhibit good electrical performance and methods of manufacturing such vertical non-volatile memory devices.

According to example embodiments, a vertical non-volatile memory device is provided that includes a substrate having a top surface that extends both in a first direction and in a second direction that is substantially perpendicular to the first direction, the substrate including a first region and a second region that surrounds the first region. The vertical non-volatile memory device further includes a plurality of gate electrodes that are stacked in a first region of the substrate in a third direction that is substantially perpendicular to both the first direction and the second direction. The device further includes a channel, conductive pads, insulation pads, contact plugs, and a first reference structure. The channel extends in the third direction through the gate electrodes. The conductive pads are in the second region of the substrate, and extend from the respective gate electrodes in the first direction. The insulation pads are in the second region of the substrate, and extend from the respective gate electrodes in the second direction. The contact plugs are electrically connected to the respective conductive pads. The first reference structure is under at least one of the insulation pads in the second region of the substrate.

In example embodiments, the first reference structure may extend in the first direction.

In example embodiments, the first region may have a rectangular shape when viewed from above, and the first reference structure may be formed in a portion of the second region that is adjacent the first region along the second direction.

In example embodiments, a plurality of additional first reference structures may be formed in the second region of the substrate, and each of the plurality of additional first reference structures may extend in the first direction.

In example embodiments, the first reference structure may include a trench in the second region of the substrate and a portion of at least one of the insulation pads that has a generally concave shape.

In example embodiments, the conductive pads may be stacked on the substrate in levels from a bottom level that is closest to the substrate to a top level that is farthest from the substrate, and the lengths of the conductive pads in the first direction may gradually decrease from the bottom level to the top level, and the insulation pads may be stacked on the substrate in levels from a bottommost level that is closest to the substrate to a topmost level that is farthest from the substrate, and the lengths of the insulation pads in the second direction may gradually decrease from the bottommost level to the topmost level.

In example embodiments, the vertical non-volatile memory device may further include a second reference structure in the second region of the substrate. The second reference structure may contact at least some of the insulation pads, and may be closer to the first region than is an end portion of a lowermost one of the insulation pads.

In example embodiments, the second reference structure may extend in the first direction.

In example embodiments, the second reference structure may include a material substantially the same as that of the insulation pads, and may include at least one layer having a generally concave shape.

In example embodiments, the conductive pads may include a material that is substantially the same as a material of the gate electrodes.

In example embodiments, the vertical non-volatile memory device may further include a tunnel insulation layer pattern, a charge storage layer pattern and a blocking layer pattern between the channel and each of the gate electrodes.

According to example embodiments, there is provided a method of manufacturing a vertical non-volatile memory device. In the method, a substrate is provided that has a first region and a second region that surrounds the first region. A first trench is formed in the second region of the substrate. A plurality of first insulation layers and a plurality of first sacrificial layer are alternately formed on the substrate. At least one of the first insulation layers and/or one of the first sacrificial layers includes a concave portion on the first trench that forms a first reference structure. The first insulation layers and the first sacrificial layers that are on the second region of the substrate are partially removed to form first insulation layer patterns and first, sacrificial layer patterns, respectively, the first insulation layer patterns and first sacrificial layer patterns comprising a first mold structure that has a staircase shape on at least two edges in which an area decreases from a bottom level to a top level. Positions and sizes of the first insulation layer patterns and the first sacrificial layer patterns are monitored using the first reference structure. A channel is formed in the first region of the substrate that extends through the first insulation layer patterns and the first sacrificial layer patterns. The first sacrificial layer patterns on the first region of the substrate are replaced with gate electrodes, respectively.

In example embodiments, after monitoring the positions and sizes of the first insulation layer patterns and the first sacrificial layer patterns, the first insulation layer patterns and the first sacrificial layer patterns are partially removed to form a second trench. A plurality of second sacrificial layers and a plurality of second insulation layers are alternately stacked on an uppermost one of the first insulation layer patterns and on an uppermost one of the first sacrificial layer patterns and on the second trench, where at least one of the second insulation layers and/or one of the second sacrificial layers includes a concave portion on the second trench that forms at least a part of a second reference structure. The second insulation layers and the second sacrificial layers on the second region of the substrate are partially removed to form second insulation layer patterns and second sacrificial layer patterns, respectively, having a staircase shape in which an area decreases from a bottom level to a top level. Positions and sizes of the second insulation layer patterns and the second sacrificial layer patterns are monitored using the second reference structure. The channel is formed through the first and second insulation layer patterns and the first and second sacrificial layer patterns. When the portions of the first sacrificial layer patterns on the first region of the substrate are replaced by the respective gate electrodes, the portions of the second sacrificial layer patterns on the first region of the substrate are also replaced by additional respective gate electrodes.

In example embodiments, when the portions of the first sacrificial layer patterns on the first region of the substrate are replaced by the respective gate electrodes, the first sacrificial layer patterns on the second region of the substrate in which the first trench is not formed may be replaced by conductive pads, respectively, the conductive pads including a material that is substantially the same as that of the gate electrodes.

In example embodiments, contact plugs that contact the respective conductive pads may be further formed.

According to example embodiments, in a method of manufacturing a vertical non-volatile memory device, a first reference structure may be formed that is used to monitor positions and/or sizes of insulation layer patterns and sacrificial layer patterns of a mold structure. The reference structure may not be formed in a peripheral circuit region but may instead be formed only in a cell region, so that the vertical non-volatile memory device may have a high integration degree regardless of the reference structure. Additionally, the reference structure may not be formed in a region in which conductive pads that contact the contact plugs are formed, and may be formed only in a region in which insulation pads are formed. Thus, the vertical non-volatile memory device may operate properly even with the reference structure.

According to example embodiments, a vertical non-volatile memory device is provided that includes a substrate having a top surface that extends in a first direction and in a second direction that is substantially perpendicular to the first direction, and a bottom surface that is spaced apart from the top surface in a third direction, the third direction being substantially perpendicular to both the first direction and the second direction. The vertical non-volatile memory device includes a plurality of gate electrodes that are stacked on the substrate in the third direction and a channel extending in the third direction through the gate electrodes. A plurality of conductive pads are stacked on the substrate in the third direction, the conductive pads extending from the respective gate electrodes in the first direction. A plurality of insulation pads extend from respective ones of the gate electrodes in the second direction, and contact plugs extend in the third direction and are electrically connected to respective ones of conductive pads. A first reference structure is provided under at least one of the insulation pads. The first reference structure comprises a trench that includes at least one material layer having a concave portion therein.

In example embodiments, the at least one material layer comprises one of the insulation pads. In some embodiments, the material layer may comprise one of the insulation pads and a concave portion of a sacrificial layer.

In example embodiments, the first reference structure may extend in the first direction.

In example embodiments, the conductive pads may be stacked on the substrate in levels from a bottom level that is closest to the substrate to a top level that is farthest from the substrate, and the lengths of the conductive pads in the first direction may gradually decrease from the bottom level to the top level. In these embodiments, the insulation pads may be stacked on the substrate in levels from a bottommost level that is closest to the substrate to a topmost level that is farthest from the substrate, and the lengths of the insulation pads in the second direction may gradually decrease from the bottommost level to the topmost level.

In example embodiments, the vertical non-volatile memory device may further include a second reference structure under at least one of the insulation pads, the second reference structure comprising a concave portion of one of the insulation pads.

In example embodiments, the second reference structure may be closer to the gate electrodes than is an end portion of a lowermost one of the insulation pads.

In example embodiments, the second reference structure may extend in the first direction.

In example embodiments, the second reference structure may overlap the first reference structure along an axis that extends in the third direction.

### BRIEF DESCRIPTION OF THE DRAWINGS

Example embodiments will be more clearly understood from the following detailed description taken in conjunction with the accompanying drawings. FIGS. 1 to 45 illustrate non-limiting, example embodiments and intermediate structures as described herein.

FIGS. 1 to 29 are cross-sectional views, plan views and perspective views illustrating stages of a method of manufacturing a vertical non-volatile memory device in accordance with example embodiments;

FIGS. 30 to 33 are cross-sectional views illustrating stages of a method of manufacturing a vertical non-volatile memory device in accordance with additional example embodiments;

FIGS. 34 to 37 are cross-sectional views illustrating stages of a method of manufacturing a vertical non-volatile memory device in accordance with further example embodiments;

FIGS. 38 to 41 are cross-sectional views illustrating stages of a method of manufacturing a vertical non-volatile memory device in accordance with still further example embodiments; and

FIGS. 42 to 45 are cross-sectional views, plan views and perspective views illustrating stages of a method of manufacturing a vertical non-volatile memory device in accordance with yet additional example embodiments;

### DESCRIPTION OF EMBODIMENTS

Various example embodiments will be described more fully hereinafter with reference to the accompanying drawings, in which some example embodiments are shown. The inventive concepts may, however, be embodied in many different forms and should not be construed as limited to the example embodiments set forth herein. Rather, these example embodiments are provided so that this description will be thorough and complete, and will fully convey the scope of the inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

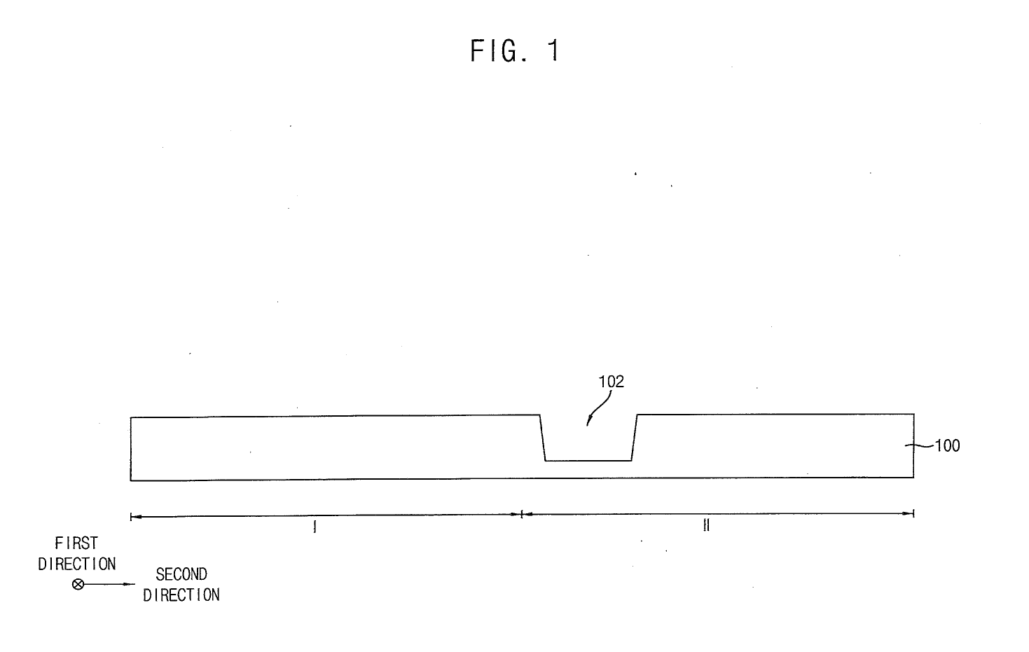

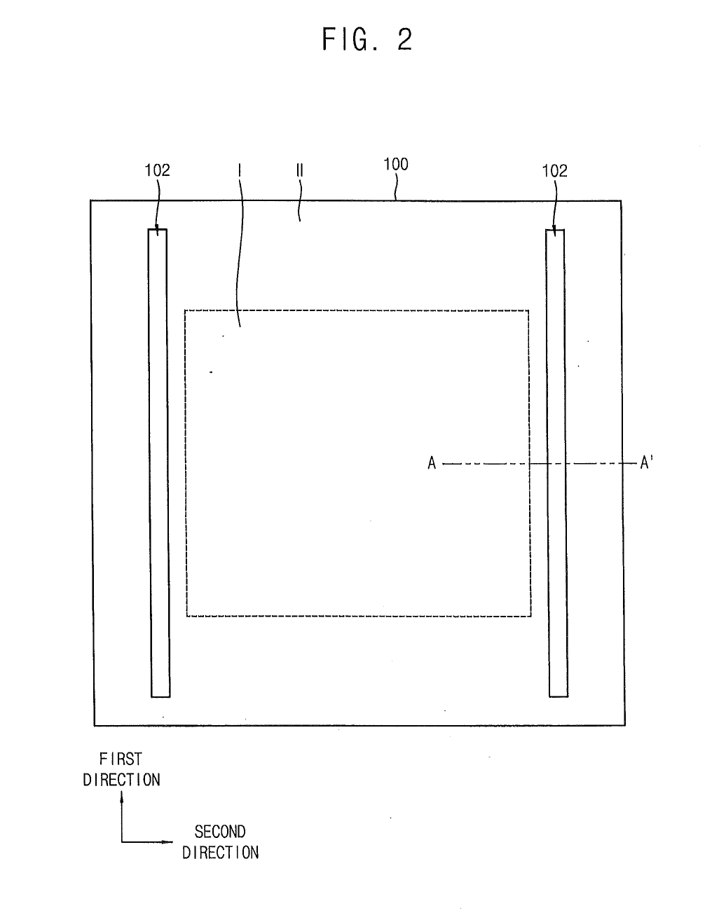

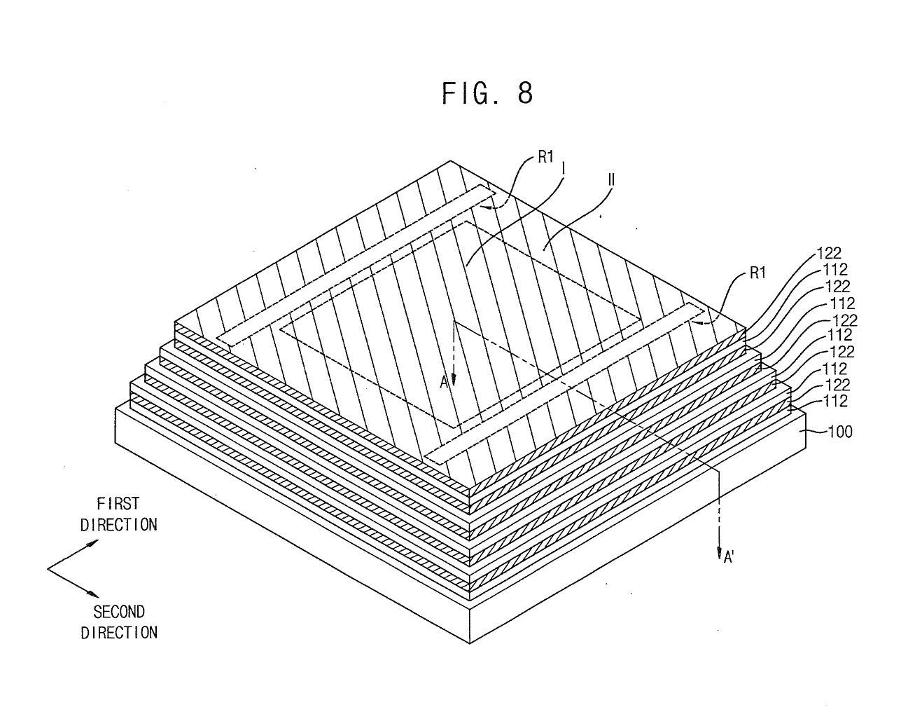

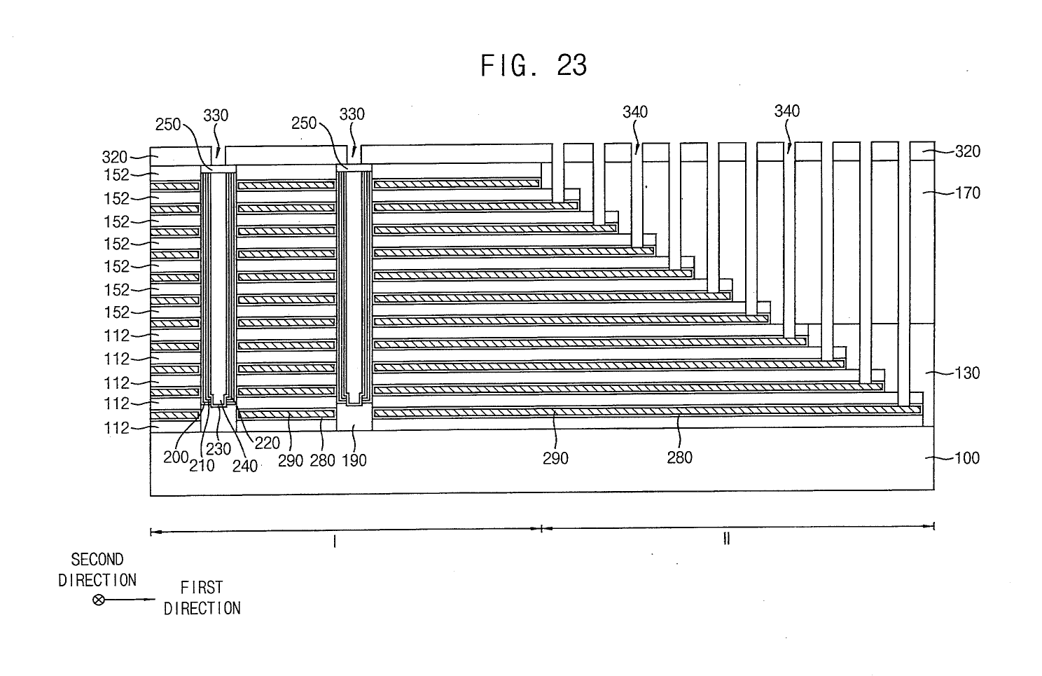

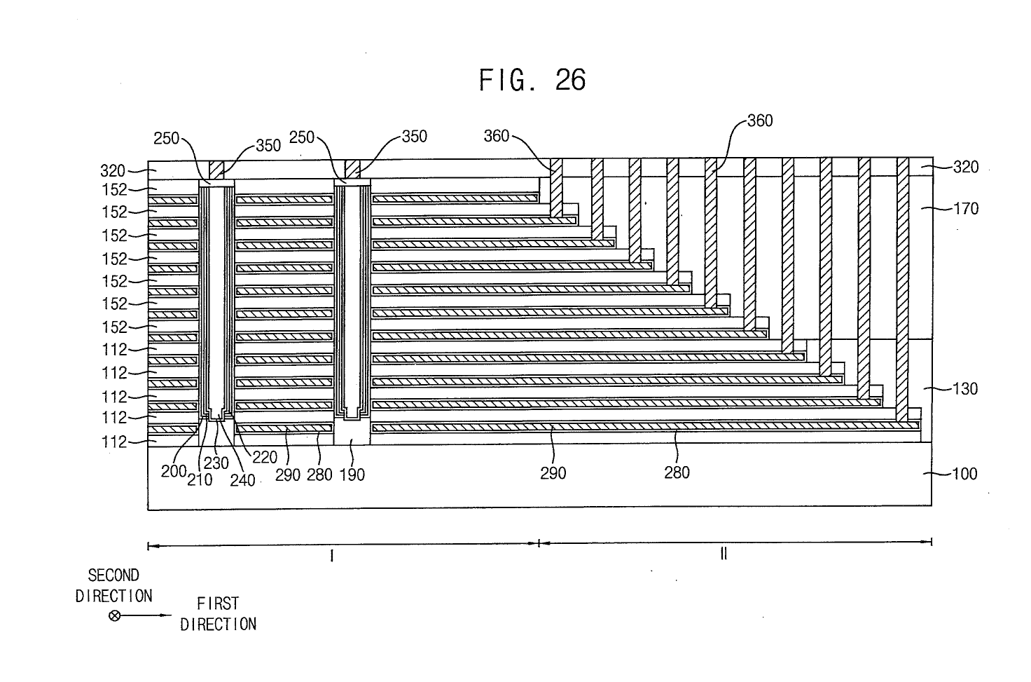

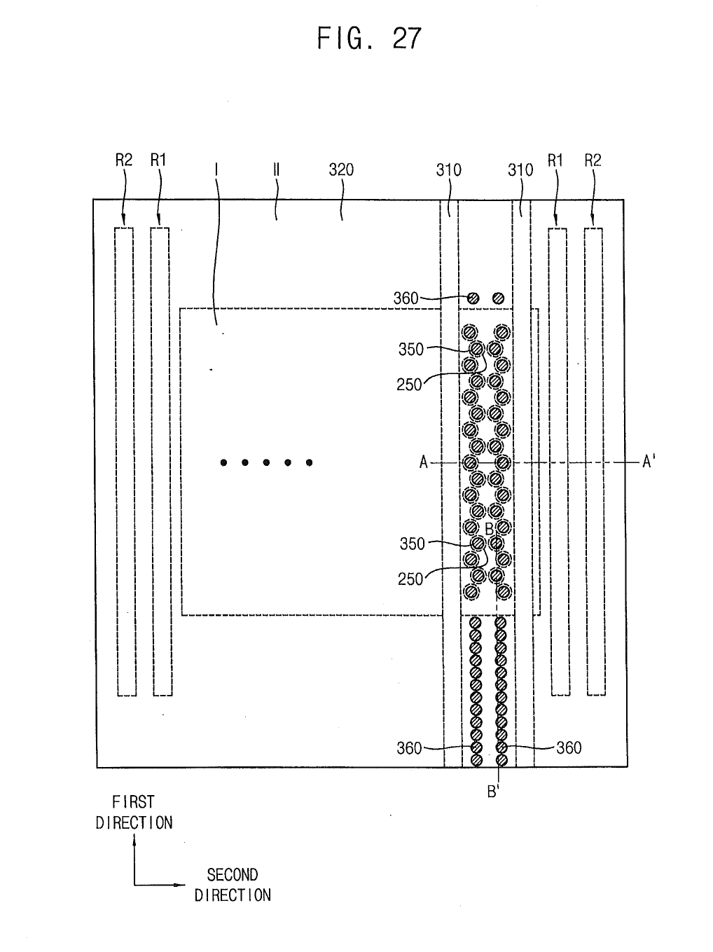

FIGS. 1 to 29 are cross-sectional views, plan views and perspective views illustrating stages of a method of manufacturing a vertical non-volatile memory device in accordance with example embodiments. Particularly, FIGS. 1, 6-7, 9-10, 12-13, 15-16, 18-19, 21-23, 25-26 and 28-29 are cross-sectional views, FIGS. 2-5, 11, 17A-17B, 20, 24 and 27 are plan views, and FIGS. 8 and 14 are perspective views. FIGS. 1, 6-7, 9-10, 12-13, 15-16, 18-19, 21-22, 25 and 28 are cross-sectional views cut along a line A-A′ that extends in a second direction substantially parallel to a top surface of a substrate, and FIGS. 23, 26 and 29 are cross-sectional views cut along a line B-B′ that extends in a first direction substantially parallel to the top surface of the substrate and substantially perpendicular to the second direction. Line A-A′ is illustrated in each of the plan and perspective views, and line B-B′ is illustrated in FIG. 27. A direction substantially perpendicular to the top surface of the substrate may be defined as a third direction, and hereinafter, the first, second and third directions may be defined as described above in all of the figures.

Referring to FIGS. 1 and 2, a substrate 100 is provided that includes a first region I and a second region II that surrounds the first region I. A first trench 102 may be formed in the second region II.

The substrate 100 may include a semiconductor material, e.g., silicon, germanium, etc. The substrate 100 may be a bulk semiconductor substrate or wafer or may be a semiconductor material that is formed on a semiconductor or non-semiconductor substrate. In example embodiments, the first region I may be a cell array region in which memory cells that each include a channel and a gate electrode are formed, and the second region II may be a pad region in which pads that extend from the gate electrodes are formed. The first and second regions I and II may define a cell region of the vertical non-volatile memory device, and the substrate 100 may further include a peripheral circuit region (not shown) in which circuits for driving the memory cells may be formed. Hereinafter, in all drawings, the peripheral circuit region is not shown, and only the cell region is shown for the convenience of explanation.

In example embodiments, the first region I may have a rectangular shape when viewed from above (i.e., when looking downwards in the third direction toward the top surface of the substrate 100), and thus the second region II which surrounds the first region I may have a rectangular ring shape when viewed from above.

In example embodiments, the first trench 102 may extend in the first direction. At least one first trench 102 may be formed in each portion of the second region II that is adjacent to the first region I in the second direction. In the example embodiment illustrated in FIG. 2, one trench 102 is provided in each portion of the second region II that is adjacent to the first region I along the second direction. In an example embodiment, the first trenches 102 may have a length in the first direction that is greater than a length of the first region I in the first direction.

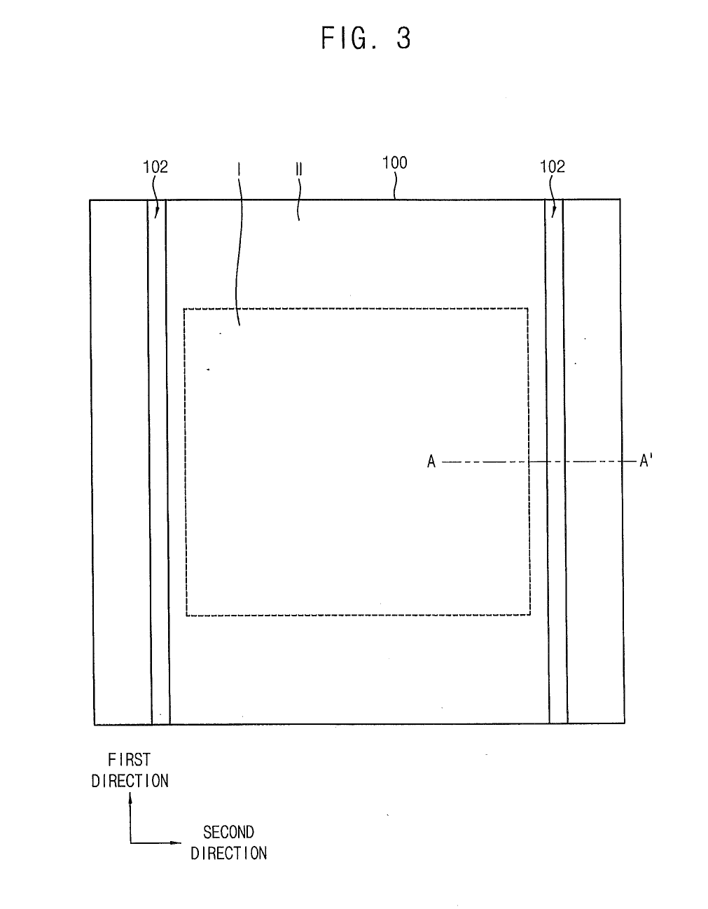

FIG. 2 illustratively shows that one first trench 102 is formed at each portion of the second region II adjacent to the lateral portion of the first region I in the second direction. The trench 102 may have a size and/or a layout that differs from the size and/or the layout shown in FIG. 2. For example, several additional configurations for the trenches 102 are shown in FIGS. 3 to 5.

Referring to FIG. 3, the first trench 102 may again be formed at each portion of the second region II that is adjacent to the first region I in the second direction like that of FIG. 2. However, in the example embodiment of FIG. 3, each trench 102 is formed to extend to both end portions of the second region II, unlike the example embodiment depicted in FIG. 2. In still further embodiments, each first trench 102 may have a length in the first direction that is smaller than a length of the first region I in the first direction.

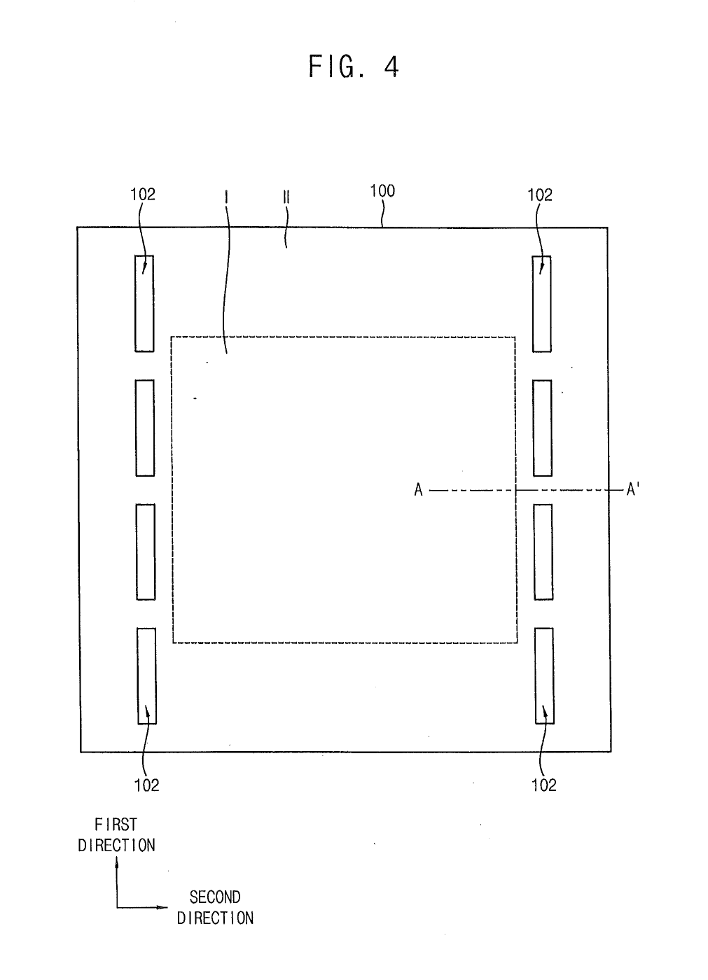

Referring to FIG. 4, at least one first trench 102 may be formed at each portion of the second region II that is adjacent to the first region I in the second direction as in the example embodiment of FIG. 2. However, in the example embodiment of FIG. 4, a plurality of first trenches 102 that have smaller lengths in the first direction are formed that are spaced apart from each other in the first direction, unlike the example embodiment depicted in FIG. 2. The trenches 102 on the first side of the first region I may be co-linear along a first line extending in the first direction, as shown in FIG. 4, and the trenches 102 on the second side of the first region I may be co-linear along a second line extending in the first direction.

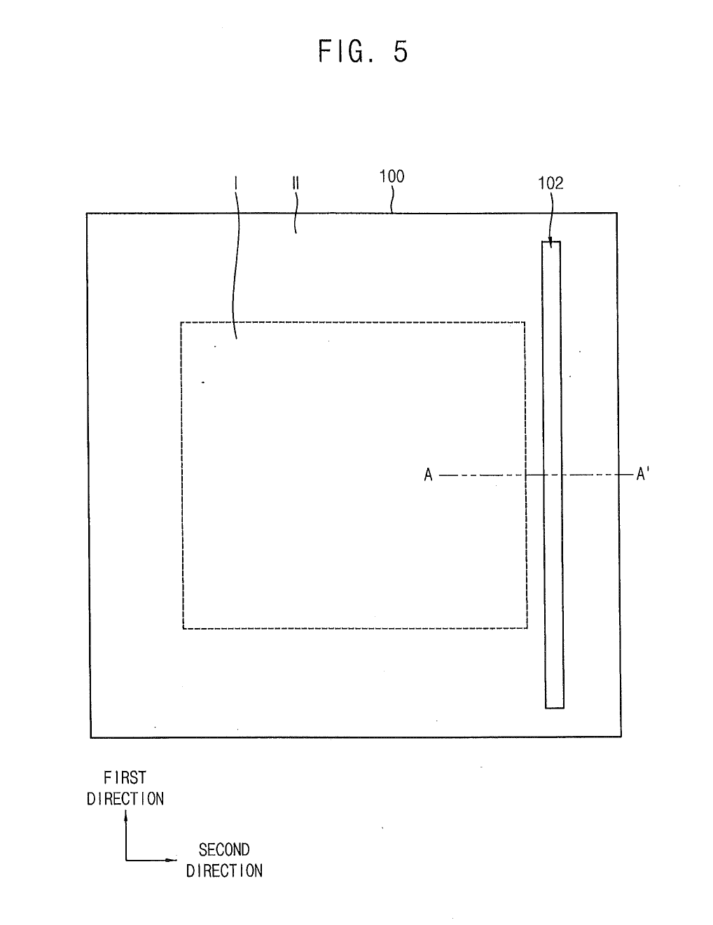

Referring to FIG. 5, unlike the example embodiment of FIG. 2, the first trench 102 may be formed only at one portion of the second region II that is adjacent to the first region I in the second direction.

Hereinafter, the example embodiment that includes the first trench 102 that is shown in FIG. 2 will be described for the convenience of explanation.

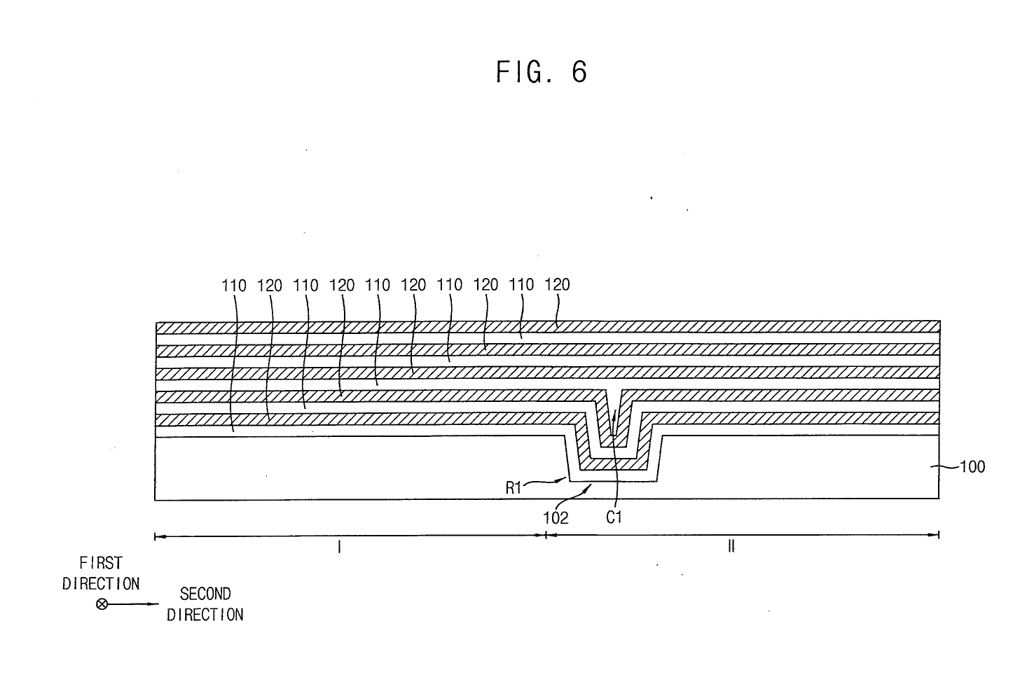

Referring to FIG. 6, a plurality of first insulation layers 110 and a plurality of first sacrificial layers 120 may be alternately formed on the substrate 100 that includes the first trench 102 therein. Thus, a plurality of first insulation layers 110 and a plurality of first sacrificial layers 120 may be alternately stacked on each other on the top surface of the substrate 100 in the third direction. FIG. 6 illustratively shows five levels of first insulation layers 110 and five levels of first sacrificial layers 120 alternately stacked on the substrate 100, however, the numbers of the first insulation layers 110 and the first sacrificial layers 120 are not limited thereto.

In example embodiments, the first insulation layers 110 and the first sacrificial layers 120 may be formed by a chemical vapor deposition (CVD) process, a plasma chemical vapor deposition (PECVD) process, an atomic layer deposition (ALD) process, etc. In an example embodiment, a lowermost one of the plurality of first insulation layers 110 that directly contacts the top surface of the substrate 100 may be formed by a thermal oxidation process.

The first insulation layers 110 may include, a silicon oxide, e.g., plasma enhanced tetraethylorthosilicate (PE-TEOS), high density plasma (HDP) oxide, plasma enhanced oxide (PEOX), etc. The first sacrificial layers 120 may include a material having an etching selectivity with respect to the first insulation layers 110, e.g., silicon nitride.

Some of the first insulation layers 110 and the first sacrificial layers 120 may have portions that have a concave shape in the first trench 102, In FIG. 6, two of the first insulation layers 110 and two of the first sacrificial layers 120 that are sequentially stacked on the top surface of the substrate 100 have portions that have a concave shape in the first trench 102. The first trench 102 and the concave portions of the first insulation layers 110 and the first sacrificial layers 120 may define a first reference structure R1, and the first reference structure R1 may have a first center C1 at a central portion thereof in the second direction.

The first trench 102 may have various sizes and/or layouts as shown in FIGS. 2 to 5, and correspondingly, the first reference structure R1 may also have various sizes and/or layouts that conform to the shape of the first trench 102.

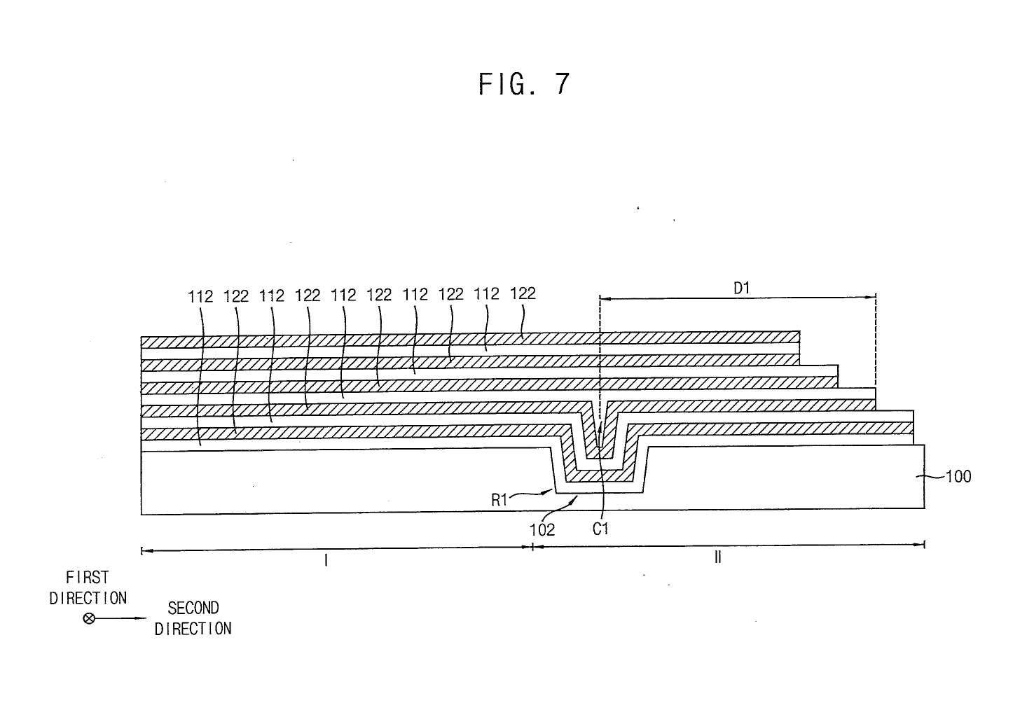

Referring to FIGS. 7 and 8, a photoresist pattern (not shown) may be formed on an uppermost one of the first sacrificial layers 120, and the first insulation layers 110 and the first sacrificial layers 120 may be etched using the photoresist pattern as an etching mask to form a plurality of first insulation layer patterns 112 and a plurality of first sacrificial layer patterns 122, respectively. The first insulation layer patterns 112 and the first sacrificial layer patterns 122 may comprise a lower mold structure.

Each first insulation pattern 112 and the first sacrificial layer pattern 122 that is directly on top of it may form a “level” of the lower mold structure. The first insulation layer patterns 112 and the first sacrificial layer patterns 122 may have widths that may gradually decrease from a bottom level to a top level of the lower mold structure both in the first and second directions, as can best be seen in the perspective view of FIG. 8. Thus, the lower mold structure may have a staircase shape, and a cross-sectional area of the lower mold structure in planes taken parallel to the top surface of the substrate 100 may decrease from the bottom level to the top level. The “bottom level” refers to the first insulation layer pattern 112 and first sacrificial layer pattern 122 that are closest to the “bottom” surface of the substrate 100 that is opposite the “top” surface of the substrate that the first insulation patters 112 and the first sacrificial patterns 122 are formed on. The “top level” refers to the first insulation layer pattern 112 and first sacrificial layer pattern 122 that are farthest from the “bottom” surface of the substrate 100. After the above-described etching step is performed, the lower mold structure may have a flat top surface in the first region I, and may have a staircase shape in the second region II.

In example embodiments, steps of the lower mold structure may be further from the first region I than is the first reference structure R1, when viewed from above. In other words, the first reference structure R1 may be between a staircase shaped portion of the second region II and the first region I.

After the lower mold structure is formed, the first reference structure R1 may be used to monitor whether the steps of the lower mold structure are formed at desired positions and/or with desired sizes. That is, the first reference structure R1 may include concave portions of at least one first insulation layer pattern 112 and/or at least one first sacrificial layer pattern 122 that are sequentially stacked in the first trench 102, and thus a first distance D1 between the first center C1 of the first reference structure R1 at a center of the concave portions in the second direction and an end portion of each of the first insulation layer patterns 112 and the first sacrificial layer patterns 122 that are sequentially stacked on the substrate 100 may be measured, so as to confirm as to whether or not the steps of the lower mold structure are formed at the desired positions and/or with the desired sizes.

Based on the result of this monitoring step, any error in the positioning of an alignment key that is used in forming the first insulation layer patterns 112 and the first sacrificial layer patterns 122 may be corrected, and/or the first insulation layer patterns 112 and the first sacrificial layer patterns 122 may be patterned additionally, so that the steps of the lower mold structure may be formed in the correct positions and/or to have the correct sizes.

The first reference structure R1 is formed within the lower mold structure, and thus no additional area is needed to form the first reference structure R1. Accordingly, the non-volatile memory device may have a high integration degree regardless of the first reference structure R1.

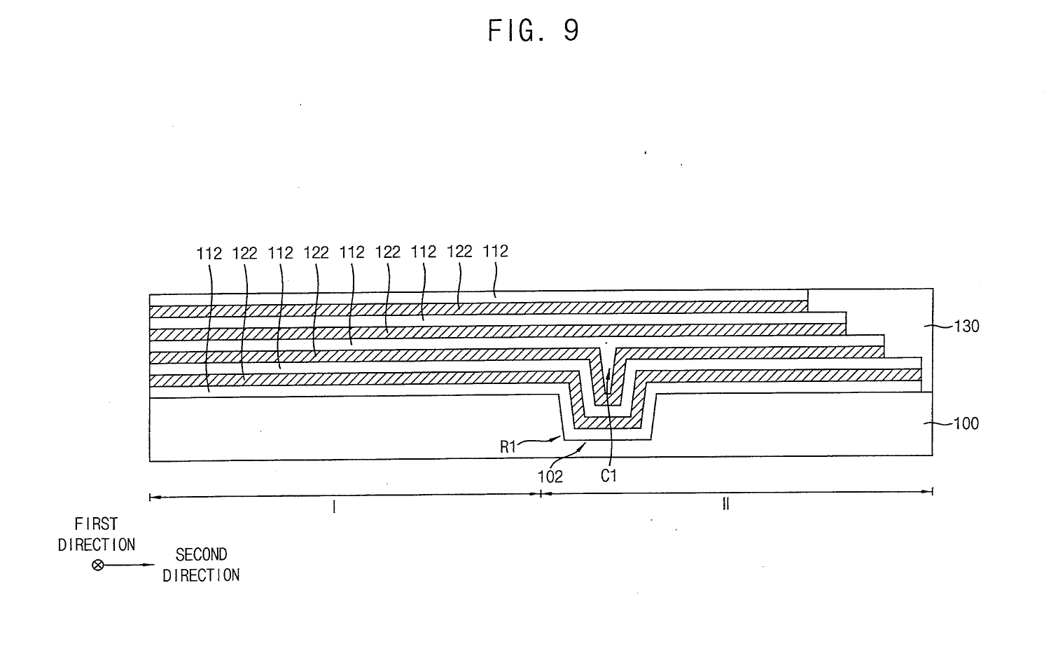

Referring to FIG. 9, a first insulating interlayer may be formed on the substrate 100 having the lower mold structure and the first reference structure R1 thereon, and the first insulating interlayer may be planarized until a top surface of the uppermost one of the first sacrificial layer patterns 122 is exposed. In example embodiments, the planarization process may be performed by a chemical mechanical polishing (CMP) process using the uppermost one of the first sacrificial layer patterns 122 as a polishing endpoint. That is, the uppermost one of the first sacrificial layer patterns 122 may serve as a polish stop layer. The planarization process may be further performed until a top surface of an uppermost one of the first insulation layer patterns 112 is exposed to form a first insulating interlayer pattern 130 that surrounds the steps of the lower mold structure on the substrate 100.

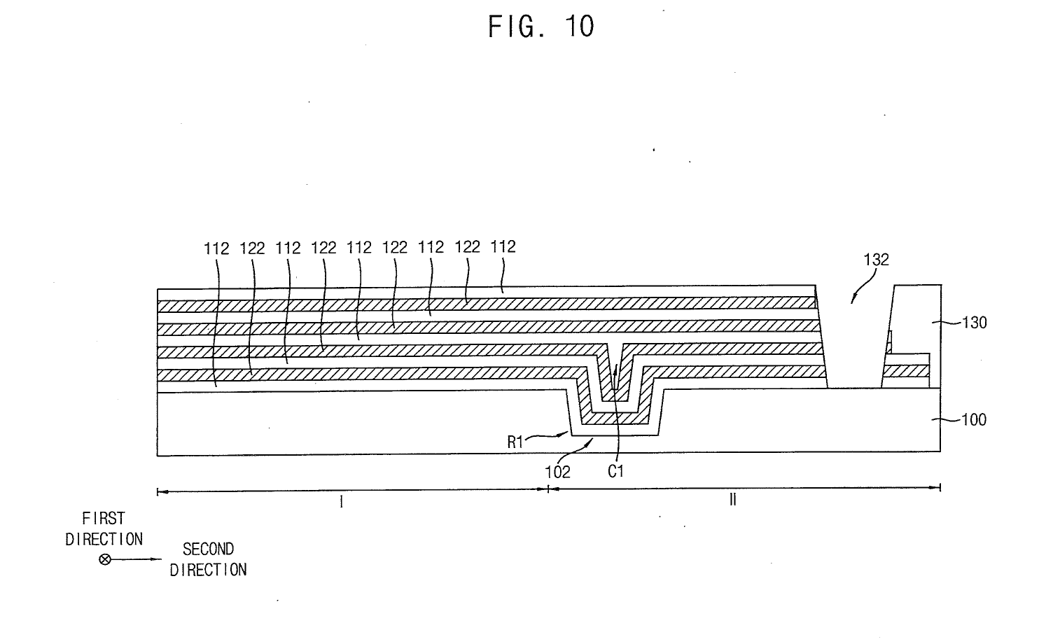

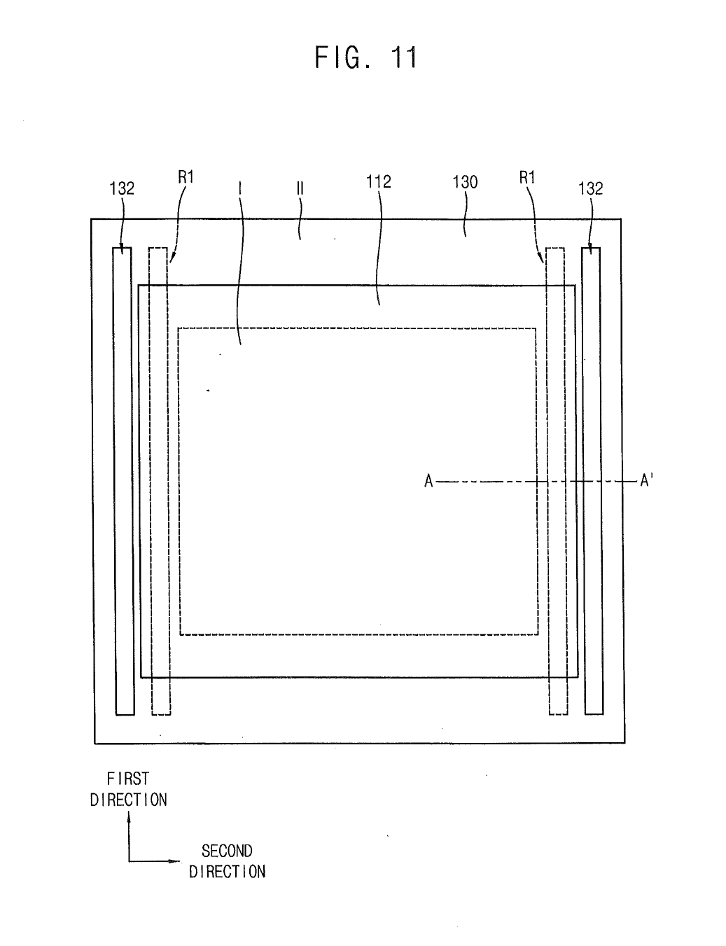

Referring to FIGS. 10 and 11, the first insulating interlayer pattern 130 and the steps of the lower mold structure, that is, portions of the first insulation layer patterns 112 and the first sacrificial layer patterns 122 that are in the second region II, may be partially etched to form a second trench 132. A top surface of the substrate 100 may be exposed by the second trench 132.

In example embodiments, the second trench 132 may have a shape, size and layout similar to those of one of the first trenches 102 shown in FIGS. 2 to 5. FIG. 11 shows that one second trench 132 is formed to extend in the first direction at each portion of the second region II adjacent to the first region I in the second direction like the first trench 102 of FIG. 2, and hereinafter, only the embodiment that includes the second trench 132 of FIG. 11 will be described for the convenience of explanation. In the present embodiment, the second trench 132 may be more distant from the first region I in the second direction than is the first trench 102.

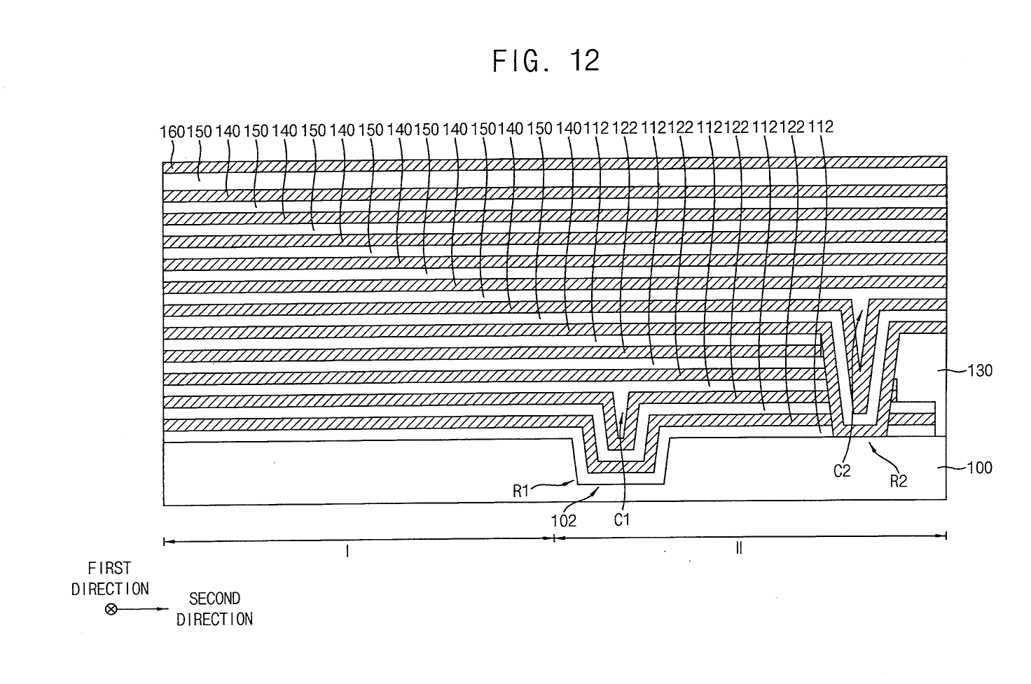

Referring to FIG. 12, a process substantially the same as or similar to that illustrated with reference to FIG. 6 may be performed.

In particular, a plurality of second sacrificial layers 140 and a plurality of second insulation layers 150 may be alternately formed on the lower mold structure, the first insulating interlayer pattern 130 and the second trench 132 so that the plurality of second sacrificial layers 140 and the plurality of second insulation layers 150 are sequentially stacked in the third direction. A polish stop layer 160 may be formed on an uppermost one of the second insulation layers 150. FIG. 12 illustratively shows seven second sacrificial layers 140 and seven second insulation layers 150, however, the number of the second sacrificial layers 140 and the second insulation layers 150 is not limited thereto.

The second sacrificial layers 140 and the second insulation layers 150 may include materials substantially the same as those of the first sacrificial layers 120 and the first insulation layers 110, respectively, and may be formed using substantially the same deposition processes. Thus, the second sacrificial layers 140 may include, e.g., silicon nitride, and the second insulation layers 150 may include, e.g., silicon oxide.

Some of the second sacrificial layers 140 and the second insulation layers 150 may have concave portions that are in the second trench 132. In FIG. 12, two of the second sacrificial layers 140 and two of the second insulation layers 150 that are sequentially stacked on the top surface of the substrate 100 have concave shaped portions that are in the second trench 132. The second trench 132 and the concave portions of the second sacrificial layers 140 and the second insulation layers 150 may define a second reference structure R2. The second reference structure R2 may have a second center C2 at a central portion thereof in the second direction.

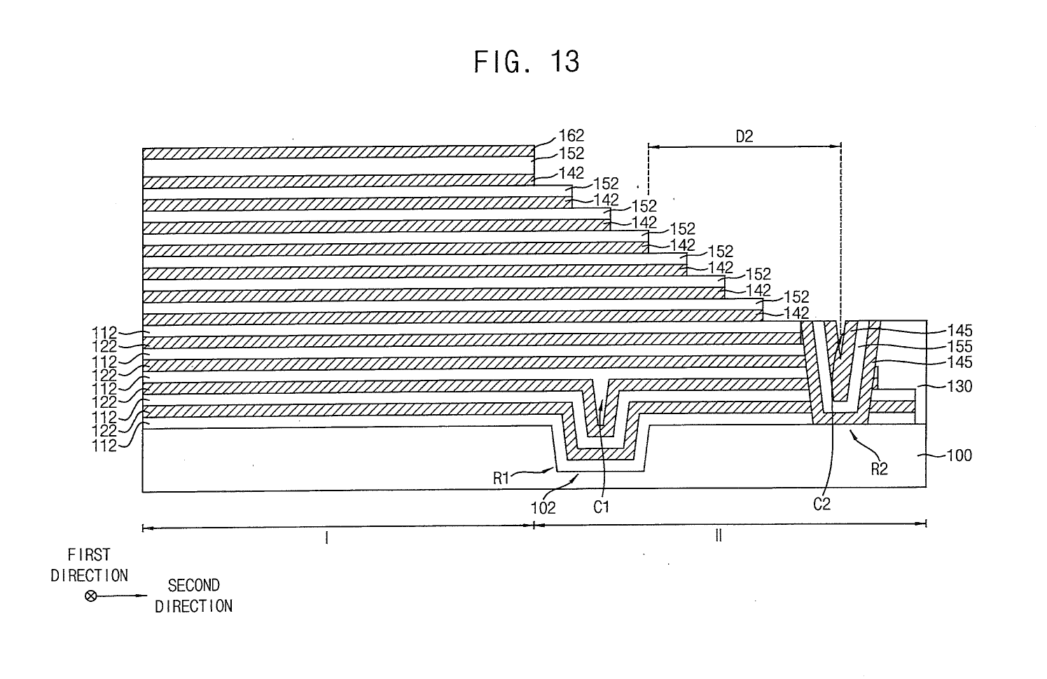

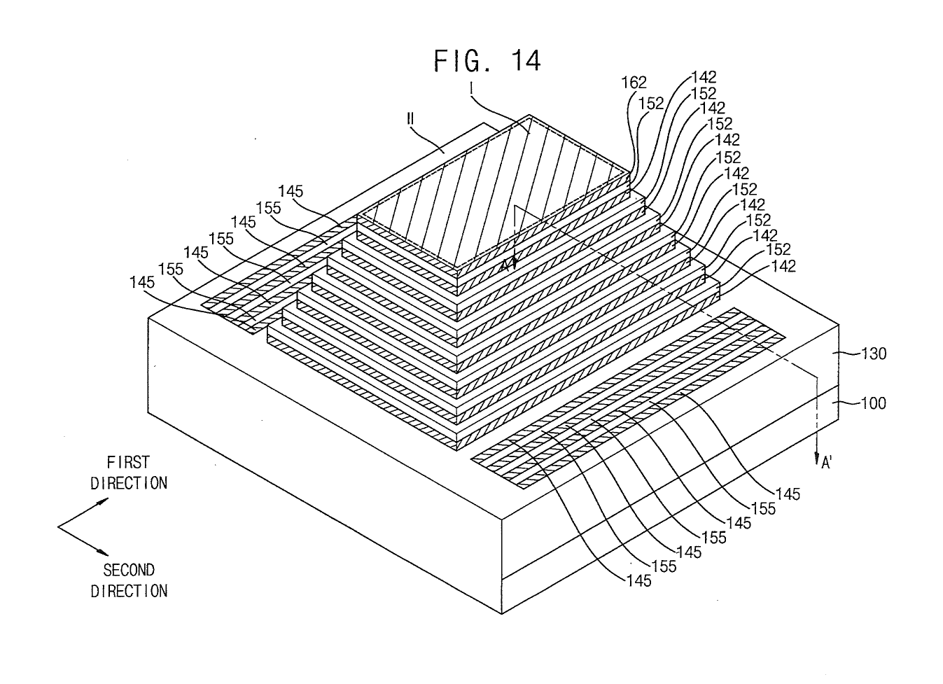

Referring to FIGS. 13 and 14, a photoresist pattern (not shown) may be formed on the polish stop layer 160, and the second sacrificial layers 140 and the second insulation layers 150 may be etched using the photoresist pattern as an etching mask to form a plurality of second sacrificial layer patterns 142 and a plurality of second insulation layer patterns 152, respectively. Additionally, a polish stop layer pattern 162 may be formed on the uppermost one of the second insulation layer patterns 152. The second sacrificial layer patterns 142 and the second insulation layer patterns 152 may comprise an upper mold structure.

Each second insulation pattern 142 and the second sacrificial layer pattern 152 that is directly on top of it may together form a “level” of the upper mold structure. The second insulation layer patterns 142 and the second sacrificial layer patterns 152 may have widths that may gradually decrease from the bottom level to the top level of the upper mold structure in both in the first and second directions, as can best be seen in the perspective view of FIG. 14. Thus, the upper mold structure may also have a staircase shape. And a cross-sectional area of the upper mold structure in planes taken parallel to the top surface of the substrate 100 may decrease from the bottom level to the top level, as can best be seen in FIG. 14. The “bottom level” refers to the second insulation layer pattern 142 and second sacrificial layer pattern 152 that are closest to the “bottom” surface of the substrate 100. The “top level” refers to the second insulation layer pattern 142 and second sacrificial layer pattern 152 that are farthest from the “bottom” surface of the substrate 100. After the above-described etching step is performed, the lower mold structure may have a flat top surface in the first region I and may have a staircase shape in the second region II. Additionally, a lowermost one of the second sacrificial layer patterns 142 may have a width that is smaller than a width of the uppermost one of the first insulation layer patterns 112.

The second reference structure R2 may contact at least one of the first insulation layer patterns 112 and/or the first sacrificial layer patterns 122 of the lower mold structure in the second region II, and when viewed from above, may be closer to the first region I than is an end portion of a lowermost one of the first insulation layer patterns 112 and the first sacrificial layer patterns 122.

In example embodiments, the stepped portion of the upper mold structure may be between the second reference structure R2 in the second region II and the first region I, when viewed from above.

The second reference structure R2 may be used to monitor whether the steps of the upper mold structure are formed at desired positions and/or with desired sizes. In particular, the second reference structure R2 comprises concave portion(s) of at least one of the second sacrificial layer patterns 152 and/or at least one of the second insulation layer patterns 152 that are sequentially stacked in the second trench 132, and thus a second distance D2 that is between the second center C2 of the second reference structure R2 at a center of the concave portions in the second direction and an end portion of each of the sequentially stacked second sacrificial layer patterns 142 and second insulation layer patterns 152 may be measured, so as to confirm as to whether the steps of the upper mold structure are formed at the desired positions and/or with the desired sizes.

Based on the results of the monitoring operation, an error of an alignment key that is used in forming the second sacrificial layer patterns 142 and the second insulation layer patterns 152 may be corrected, or the second sacrificial layer patterns 142 and the second insulation layer patterns 152 may be patterned further, so that the steps of the upper mold structure may be formed at desired positions and/or with desired sizes.

The second reference structure R2 is formed within a region in which the lower mold structure is formed when viewed from above, and thus no additional area is required for forming the second reference structure R2. Accordingly, the non-volatile memory device may include the second reference structure R2 yet still have a high degree of integration.

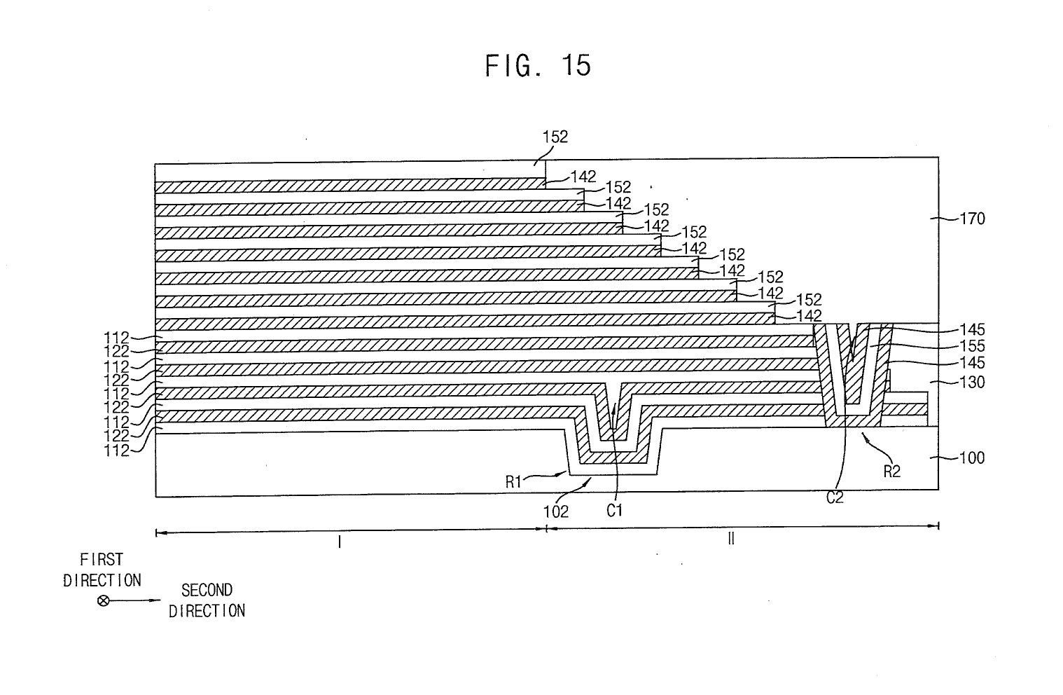

Referring to FIG. 15, a second insulating interlayer may be formed on the substrate 100 having the lower and upper mold structures and the first and second reference structures R1 and R2 and the first insulating interlayer pattern 130 thereon, and the second insulating interlayer may be planarized until a top surface of the polish stop layer pattern 162 is exposed. In example embodiments, the planarization process may be performed by a chemical mechanical polishing (CMP) process. As shown in FIG. 15, the planarization process may be continued until a top surface of the uppermost one of the second insulation layer patterns 152 is exposed to form a second insulating interlayer pattern 170 that surrounds the stepped portion of the upper mold structure.

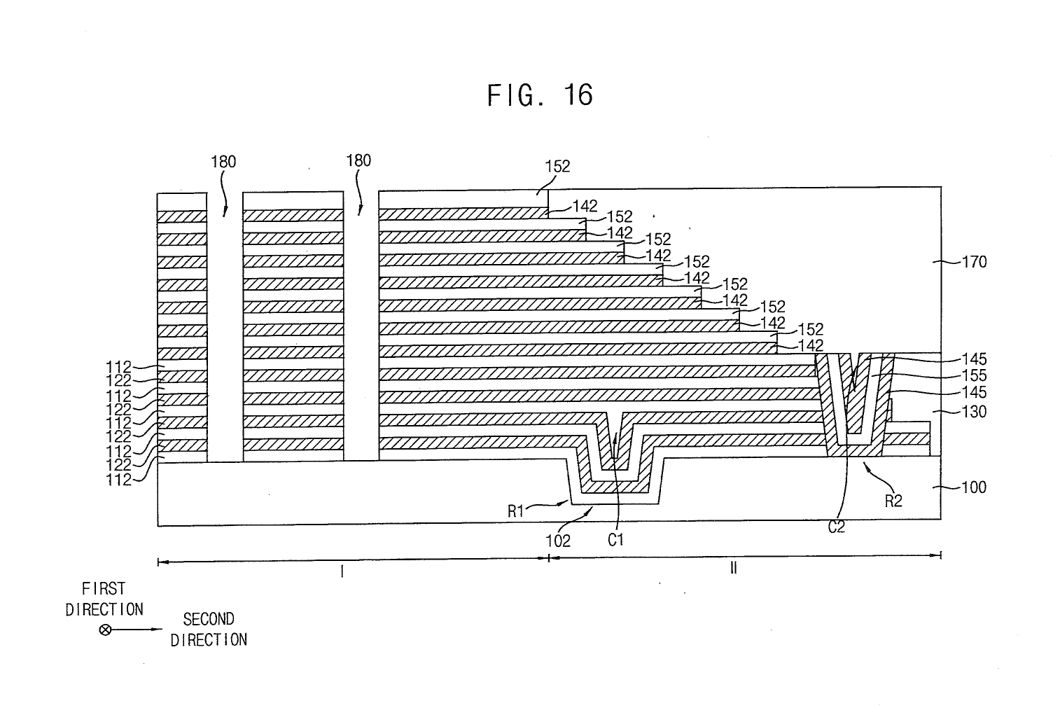

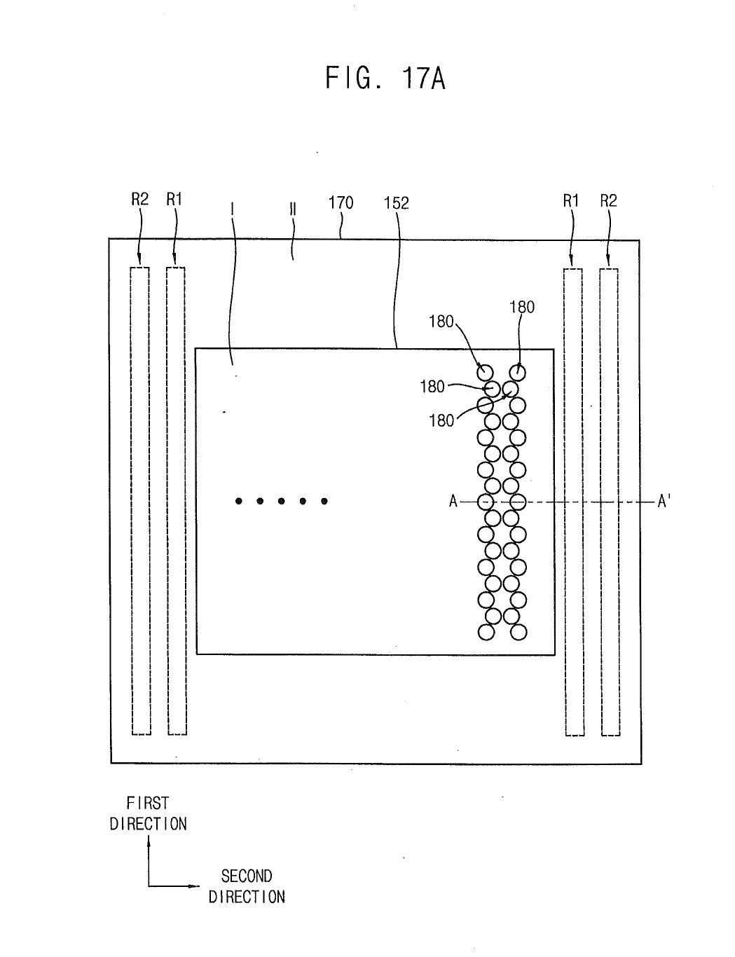

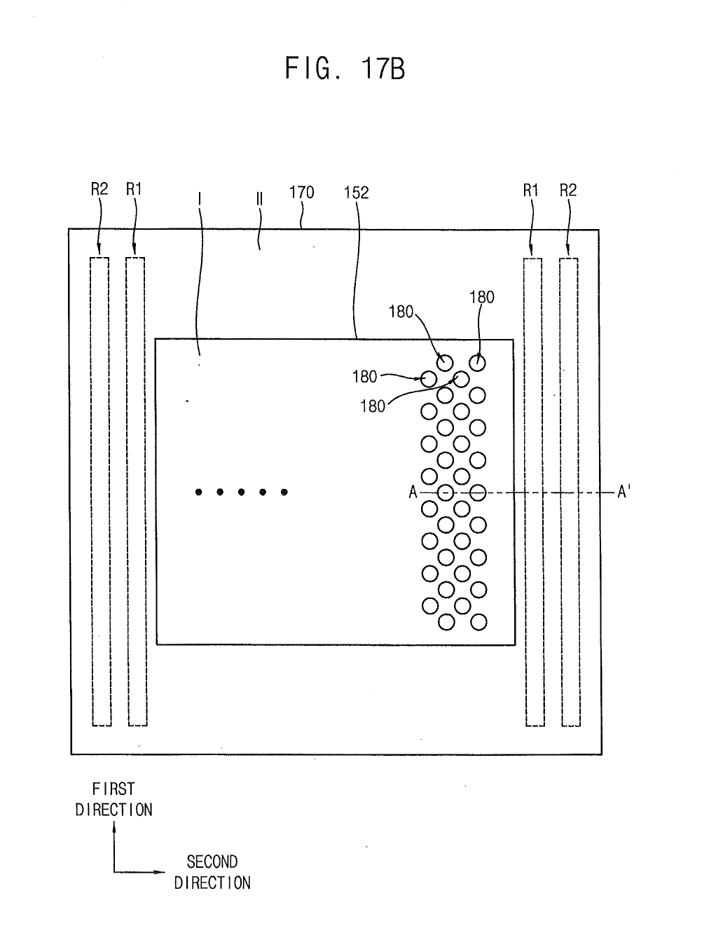

Referring to FIGS. 16 and 17A, a plurality of holes 180 may be formed through the first and second insulation layer patterns 112 and 152 and the first and second sacrificial layer patterns 122 and 142 in the first region I. Each of the holes 180 may expose the top surface of the substrate 100.

In example embodiments, the holes 180 may be formed in the first and second directions, and may define a hole array. In example embodiments, the hole array may include a first hole column that includes a plurality of first holes 180 that extends in the first direction, and a second hole column that includes a plurality of second holes 180 that also extends in the first direction. The second hole column may be spaced apart from the first hole column along the second direction. The first holes 180 may be disposed at acute angles from the second holes 180 along the first direction or the second direction. Thus, the first and second holes 180 may be arranged in a zigzag layout in the first direction so as to be densely formed in a unit area.

Additionally, the hole array may further include third and fourth hole columns that are spaced apart from the first hole column in the second direction. In example embodiments, the third and fourth hole columns may be disposed to be symmetrical to the second and first hole columns, respectively, with an imaginary surface adjacent to the second hole column defined by the first and third directions as a plane of symmetry. Thus, a distance between the first hole column and the fourth hole column may be greater than a distance between the second hole column and the third hole column.

The first to fourth hole columns may define a hole set, and a plurality of hole sets may be disposed in the second direction to form the hole array. FIG. 17A shows illustratively one hole set of the hole array.

FIG. 17B shows another hole array that is different from that of FIG. 17A. That is, in one hole set, the first and second hole columns are not symmetrical to the fourth and third hole columns, respectively, with an imaginary surface as a plane of symmetry, but a distance between the first hole column and the third hole column may be substantially the same as a distance between the second hole column and the fourth hole column.

FIGS. 17A and 17B illustratively show example embodiments of the hole arrays, and the vertical non-volatile memory device may have various other types of hole arrays. Hereinafter, only the case including the hole array shown in FIG. 17A will be described.

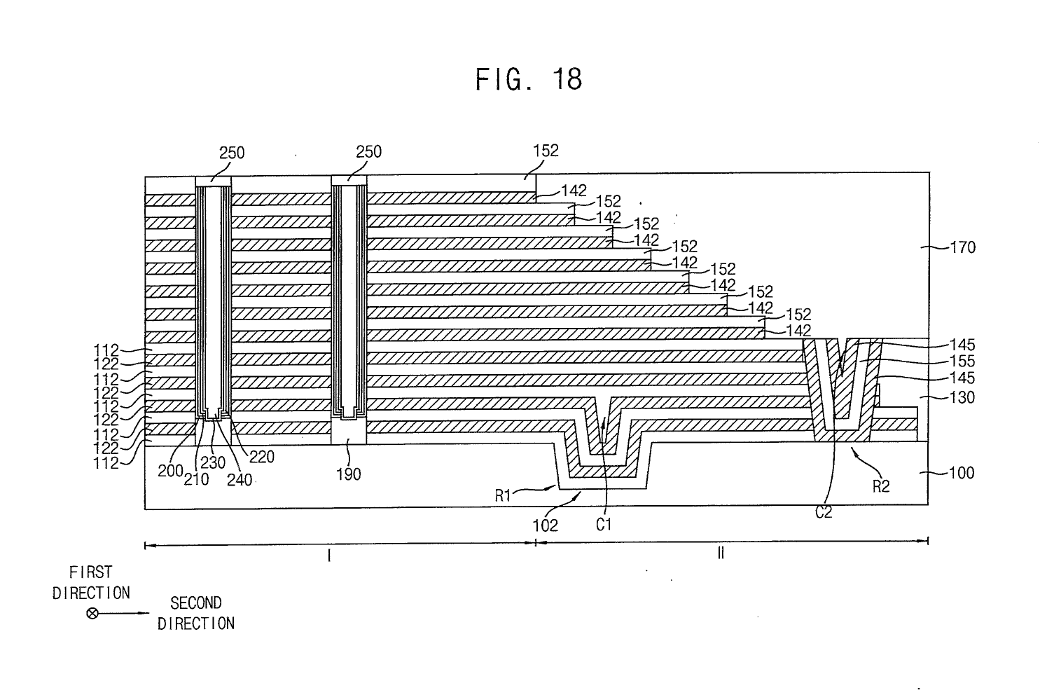

Referring to FIG. 18, a semiconductor pattern 190 may be formed to partially fill each hole 180.

In particular, a selective epitaxial growth (SEG) process may be performed using the exposed top surface of the substrate 100 as a seed to form the semiconductor pattern 190. The semiconductor pattern 190 may fill a bottom portion of each of the holes 180. If the substrate 100 is a silicon substrate or a germanium substrate, the semiconductor pattern 190 may be single crystalline silicon or single crystalline germanium, respectively. In some cases, impurities may be doped into the semiconductor pattern 190. In other embodiments, an amorphous silicon layer may be formed to fill the holes 180, and a laser epitaxial growth (LEG) process or a solid phase epitaxy (SPE) process may be performed on the amorphous silicon layer to form the semiconductor pattern 190.

A first blocking layer, a charge storage layer, a tunnel insulation layer and a spacer layer (not shown) may be sequentially formed on inner walls of the holes 180, top surfaces of the semiconductor patterns 190, a top surface of the uppermost one of the second insulation layer patterns 152 and a top surface of the second insulating interlayer pattern 170. The spacer layer may be anisotropically etched to form spacers (not shown) on the inner walls of the holes 180, respectively. The tunnel insulation layer, the charge storage layer and the first blocking layer may be etched using the spacers as an etching mask to form a tunnel insulation layer pattern 220, a charge storage layer pattern 210 and a first blocking layer pattern 200, respectively, on the inner walls of the holes 180 and on the semiconductor patterns 190. Each of the tunnel insulation layer pattern 220, the charge storage layer pattern 210 and the first blocking layer pattern 200 may have a cup shape that has an opening in the central bottom portion thereof. The top surfaces of the semiconductor patterns 190 may be exposed through these openings.

In example embodiments, the first blocking layer may include an oxide, e.g., silicon oxide, the charge storage layer may include a nitride, e.g., silicon nitride, the tunnel insulation layer may include an oxide, e.g., silicon oxide, and the spacer layer may include a nitride, e.g., silicon nitride.

After removing the spacers, a channel layer may be formed on the exposed top surfaces of the semiconductor patterns 190, the tunnel insulation layer patterns 220, the uppermost one of the second insulation layer patterns 152 and the second insulating interlayer pattern 170, and a first filling layer may be formed on the channel layer to sufficiently fill remaining portions of the holes 180.

In example embodiments, the channel layer may include doped or undoped polysilicon or amorphous silicon. When the channel layer includes amorphous silicon, an LEG process or an SPE process may be performed so that the amorphous silicon layer is converted into a crystalline silicon layer. The first filling layer may include an oxide, e.g., silicon oxide.

The first filling layer and the channel layer may be planarized until the top surface of the uppermost one of the second insulation layer patterns 152 and/or the top surface of the second insulating interlayer pattern 170 are exposed to form a first filling layer pattern 240 that fills the remaining portion of each hole 180, and the channel layer may be transformed into a channel 230 in each hole 180.

Thus, the first blocking layer pattern 200, the charge storage layer pattern 210, the tunnel insulation layer pattern 220, the channel 230 and the first filling layer pattern 240 may be sequentially stacked on the semiconductor pattern 190 in each hole 180. Each of the first blocking layer pattern 200, the charge storage layer pattern 210 and the tunnel insulation layer pattern 220 may have a cup shape of which a central bottom is opened, the channel 230 may have a cup shape, and the first filling layer pattern 240 may have a pillar shape.

As the holes 180 define the hole array including the first and second holes 180, and as the channels 230 are formed in the holes 180, the channels 230 may define a channel array including first and second channels 230.

An upper portion of a first structure that includes the first filling layer pattern 240, the channel 230, the tunnel insulation layer pattern 220, the charge storage layer pattern 210 and the first blocking layer pattern 200 that are sequentially stacked in each hole 180 may be removed to form a recess (not shown), and a capping layer pattern 250 may be formed on the first structure in each hole 180 to fill these recesses.

In some embodiments, upper portions of the first structures may be removed via an etch back process, and then a capping layer may be formed on the first structures to fill the recesses created by removal of the upper portion of each first structure. Then, the uppermost one of the second insulation layer patterns 152 and the second insulating interlayer pattern 170, and an upper portion of the capping layer may be planarized until the top surface of the uppermost one of the second insulation layer patterns 152 and/or the top surface of the second insulating interlayer pattern 170 are exposed to form the capping layer pattern 250 in each hole 180. In example embodiments, the capping layer may include doped or undoped polysilicon or amorphous silicon. When the capping layer includes amorphous silicon, a crystallization process may be further performed thereon.

The capping layer patterns 250 may be formed on the channels 230, and thus may form a capping layer pattern array in accordance with the channel array.

The first structure, the semiconductor pattern 190 and the capping layer pattern 250 in each hole 180 may form a second structure.

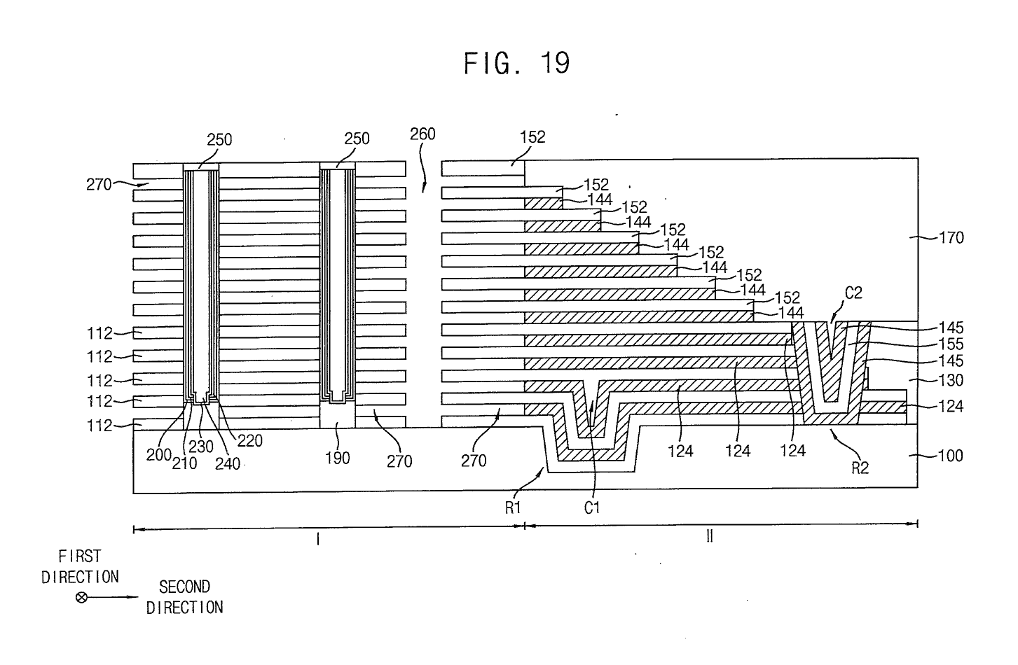

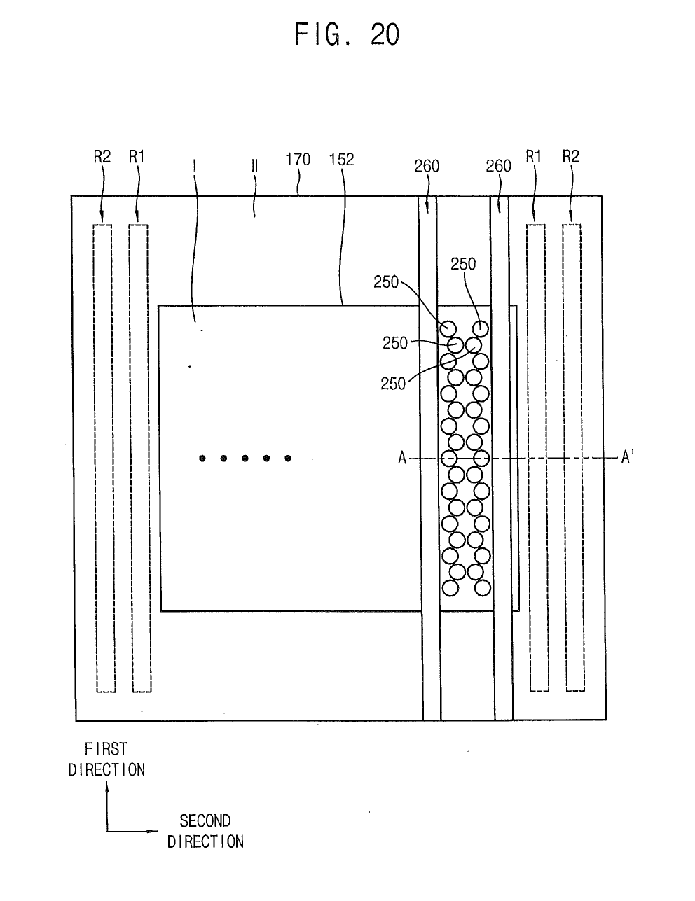

Referring to FIGS. 19 and 20, a first opening 260 may be formed through the first and second insulation layer patterns 112 and 152 and the first and second sacrificial layer patterns 122 and 142 to expose a top surface of the substrate 100. As shown in FIG. 20, the first opening 260 may have a trench shape when viewed from above.

In example embodiments, a plurality of first openings 260 may be formed along the second direction, and each of the first openings 260 may extend in the first direction. However, the first openings 260 may not be formed at portions of the second region II that include the first and second reference structures R1 and R2. That is, the first openings 260 may be formed in the first region I, and may extend to portions of the second region II that are adjacent to the first region I in the first direction, however, the first openings 260 may not be formed in the portions of the second region II that are adjacent to the first region I in the second direction.

In example embodiments, one first opening 260 may be formed between neighboring hole sets, and FIG. 20 illustratively shows two first openings 260 at both sides of one hole set (note that FIG. 19 only shows the edge of the second of the first openings 260).

The first and second sacrificial layer patterns 122 and 142 exposed by the first openings 260 may be removed to form gaps 270 between the first and second insulation layer patterns 112 and 152 at adjacent levels. Portions of outer sidewalls of the first blocking layer patterns 200 and sidewalls of the semiconductor patterns 190 may be exposed by the gaps 270. In example embodiments, the first and second sacrificial layer patterns 122 and 142 that are exposed by the first openings 260 may be removed by, for example, a wet etch process using an etch solution including phosphoric acid and/or sulfuric acid.

However, as shown in FIG. 19, the first openings 260 may not be formed in the portions of the second region II that are adjacent to the first region I in the second direction, and thus portions of the first and second sacrificial layer patterns 122 and 142 may not be removed by the wet etching process but instead may remain in the device structure. These remaining portions of the first and second sacrificial layer patterns 122, 142 may be referred to as first and second insulation pads 124 and 144, respectively.

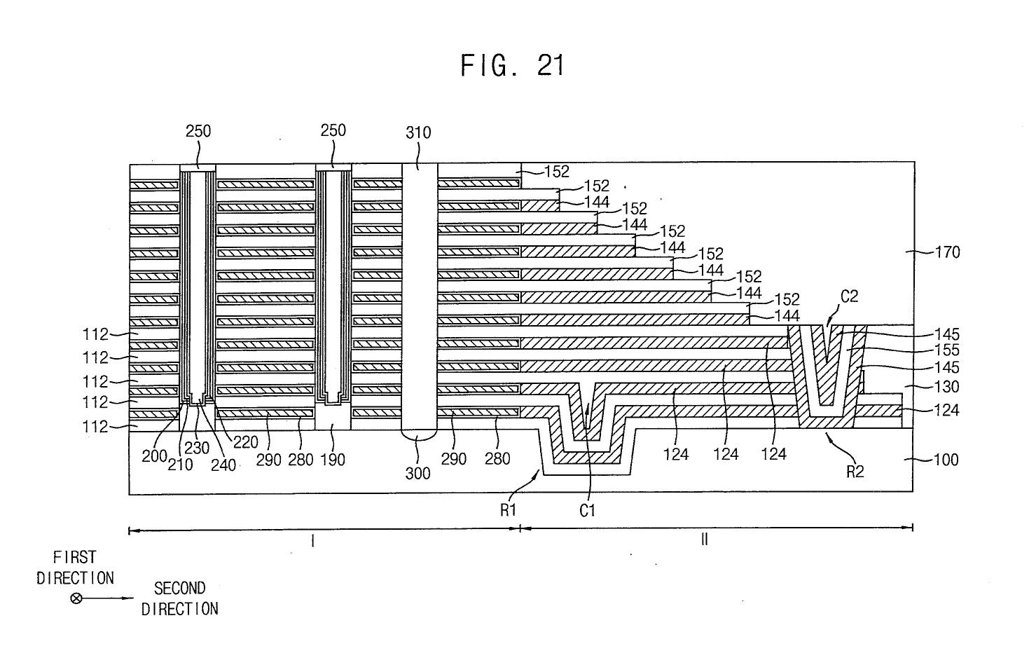

Referring to FIG. 21, a second blocking layer may be formed on the exposed portions of the outer sidewalls of the first blocking layer patterns 200, the exposed portions of the sidewalls of the semiconductor patterns 190, inner walls of the gaps 270, surfaces of the first and second insulation layer patterns 112 and 152, the exposed top surface of the substrate 100, a top surface of the capping layer pattern 250 and a top surface of the second insulating interlayer pattern 170, and a conductive layer may be formed on the second blocking layer to sufficiently fill remaining portions of the gaps 270.

The second blocking layer may include a metal oxide, e.g., aluminum oxide, hafnium oxide, lanthanum oxide, lanthanum aluminum oxide, lanthanum hafnium oxide, hafnium aluminum oxide, titanium oxide, tantalum oxide and/or zirconium oxide.

The conductive layer may include a metal and/or a metal nitride. For example, the conductive layer may include a metal having a low resistance, e.g., tungsten, titanium, tantalum, platinum, etc., or a metal nitride thereof; e.g., titanium nitride, tantalum nitride, etc.

The conductive layer may be partially removed to form a conductive structure 290 in each gap 270. In example embodiments, the conductive layer may be partially removed by a wet etching process.

In example embodiments, each conductive structure 290 may extend in the first direction in the first region I, and may further extend to a portion of the second region II that is adjacent to the first region I in the first direction. Hereinafter, a portion of each conductive structure 290 in the first region I may be referred to as a gate electrode, and a portion of each conductive structure 290 in the second region II may be referred to as a conductive pad. The conductive pads that are substituted for the first sacrificial layer pattern 122 may be referred to as first conductive pads, and the conductive pads that are substituted for the second sacrificial layer pattern 142 may be referred to as second conductive pads.

In example embodiments, the gate electrode may include a ground select line (GSL), a word line and a string select line (SSL) that are sequentially stacked on the substrate 100. Each of the GSL, the word line and the SSL may be formed at a single level or at a plurality of levels. In example embodiments, the GSL may be formed at one level, the SSL may be formed at two levels, and the word line may be formed at eight levels that are between the GSL and the SSL. However, the numbers of the GSL, the word line and the SSL may not be limited thereto. The GSL may be formed adjacent to the semiconductor patterns 190, and the word line and the SSL may be formed adjacent to the channels 230.

When the conductive layer is partially removed, portions of the second blocking layer that are on surfaces of the first and second insulation layer patterns 112 and 152, on the top surface of the substrate 100, on the top surface of the capping layer patterns 250 and on the top surface of the second insulating interlayer pattern 170 may also be removed to form a second blocking layer pattern 280 that surrounds sidewalls of the conductive structure 290 in each gap 270. The first and second blocking layer patterns 200 and 280 may define a blocking layer pattern structure.

As the conductive layer and the second blocking layer are partially removed, the first opening 260 that exposes a top surface of the substrate 100 and that extends in the first direction may be formed again, and impurities may be implanted into the exposed top surface of the substrate 100 to form an impurity region 300. In example embodiments, the impurities may include n-type impurities, for example, phosphorus and/or arsenic. In example embodiments, the impurity region 300 may extend in the first direction and serve as a common source line (CSL).

A metal silicide pattern (not shown), e.g., a cobalt silicide pattern or a nickel silicide pattern may be formed on the impurity region 300.

A second filling layer pattern 310 may be formed to fill each of the first openings 260. In example embodiments, a second filling layer is formed on the substrate 100, the uppermost one of the second insulation layer patterns 152, the capping layer patterns 250 and the second insulating interlayer pattern 170 to fill the first openings 260. Then, an upper portion of the second filling layer may be planarized until the top surface of the uppermost one of the second insulation layer patterns 152 and/or the top surface of the second insulating interlayer pattern 170 may be exposed to form the second filling layer pattern 310 in each first opening 260.

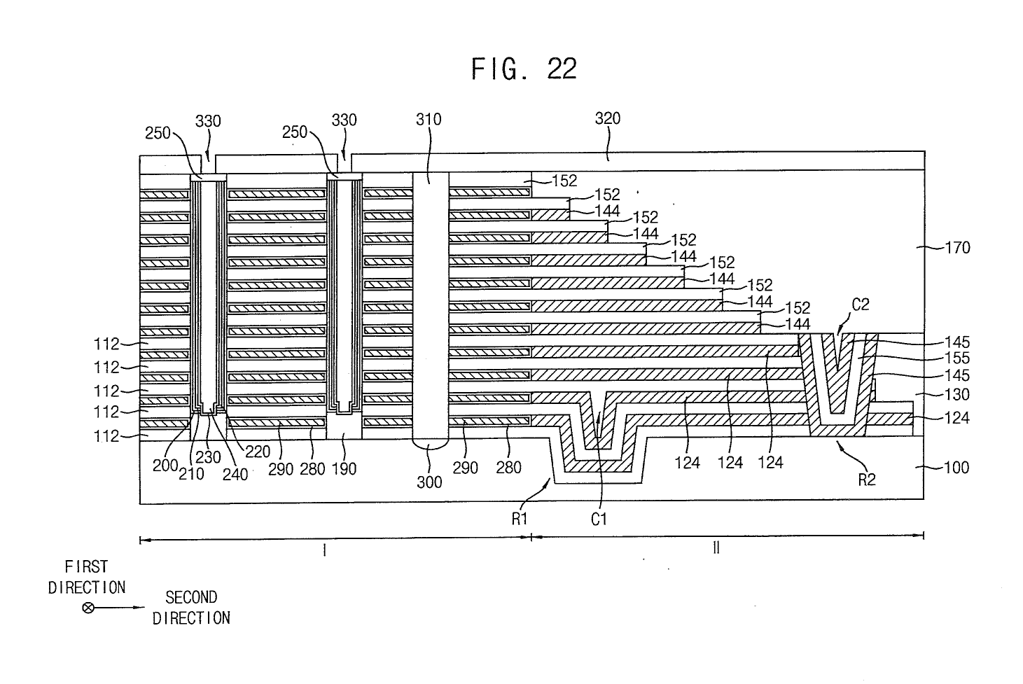

Referring to FIGS. 22 to 24, after forming a third insulating interlayer 320 on the uppermost one of the second insulation layer patterns 152, the capping layer patterns 250, the second insulating interlayer pattern 170 and the second filling layer patterns 310, the third insulating interlayer 320 may be partially removed to form second openings 330 that expose top surfaces of the respective capping layer patterns 250. Additionally, the third insulating interlayer 320, the second insulating interlayer pattern 170, the first insulating interlayer pattern 130, the first and second insulation layer patterns 122 and 142 and the second blocking layer pattern 280 may be partially removed to form third openings 340 that expose top surfaces of the respective conductive pads. The second openings 330 may be formed in the first region I, and the third openings 340 may be formed in the second region II. The third openings 340 may not be formed in the portions of the second region II that are adjacent to the first region I in the second direction, and thus the first and second insulation pads 124 and 144 may not be exposed in these portions of the second region II.

The second openings 330 may define a second opening array. In example embodiments, the ones of the third openings 340 that are generally aligned with the first and second hole columns in the first direction may define a first opening column, and the ones of the third openings 340 that are generally aligned with the third and fourth hole columns in the first direction may define a second opening column. The first and second opening columns may define a third opening array. Alternatively, when the holes 180 are arranged as shown in FIG. 17B, the third opening array may include a plurality of opening columns that may correspond to the hole columns, respectively.

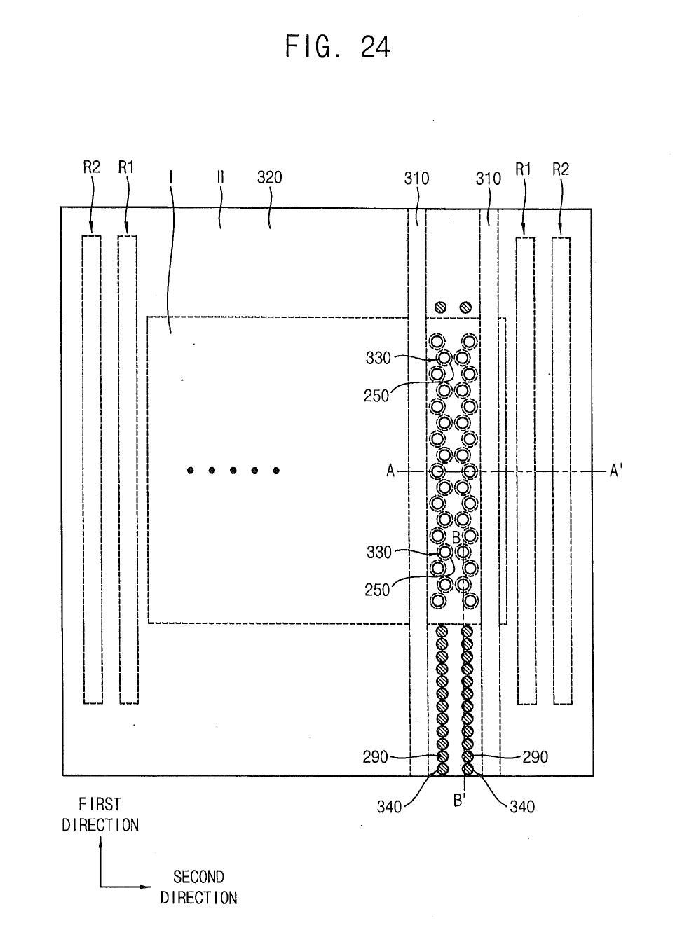

FIG. 24 shows that a plurality of third openings 340 are formed at a first portion of the second region II that is adjacent to the first region I in the first direction and that a pair of third openings 340 are formed at a second portion of the second region II that is adjacent to the first region I in the first direction, however, the numbers and/or the layouts of the third openings 340 may not be limited thereto. That is, a plurality of third openings 340 may be also formed at the second portion of the second region II.

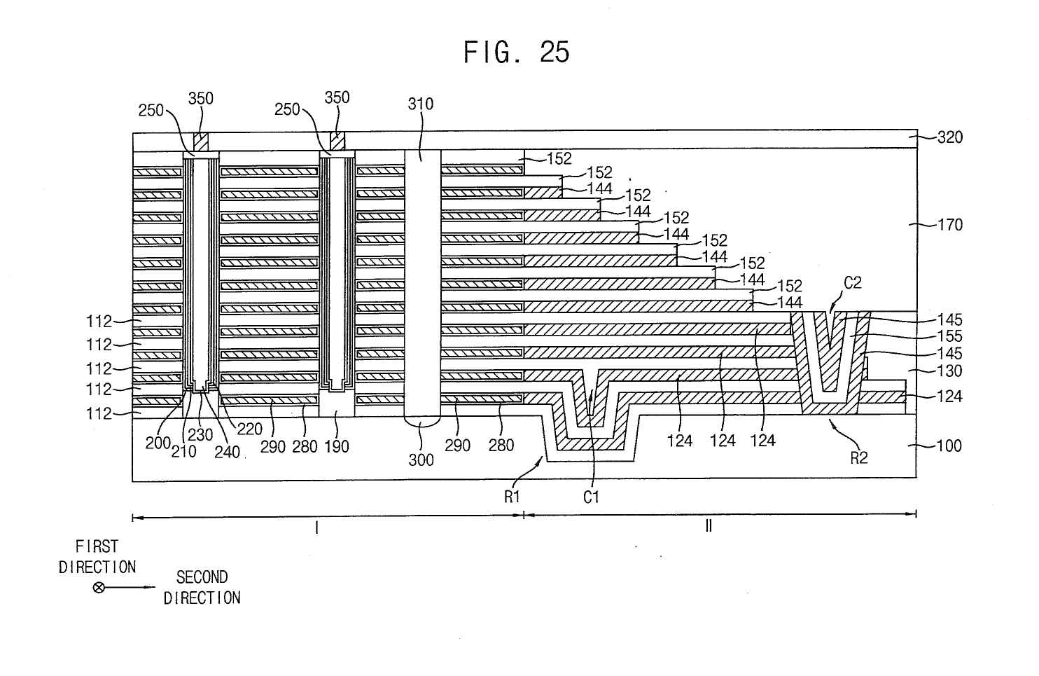

Referring to FIGS. 25 to 27, a plurality of bit line contacts 350 may be formed in the second openings 330 on the respective capping layer patterns 250, and a plurality of first contact plugs 360 may be formed on the conductive pads that fill the third openings 340.

In example embodiments, the bit line contacts 350 and the first contact plugs 360 may be formed by forming a contact layer on the exposed capping layer patterns 250, the exposed conductive pads and the third insulating interlayer 320 to a thickness that is sufficient to fill the second and third openings 330 and 340, and by then planarizing an upper portion of the contact layer until the top surface of the third insulating interlayer 320 is exposed. The contact layer may include, e.g., a metal, a metal nitride and/or doped polysilicon.

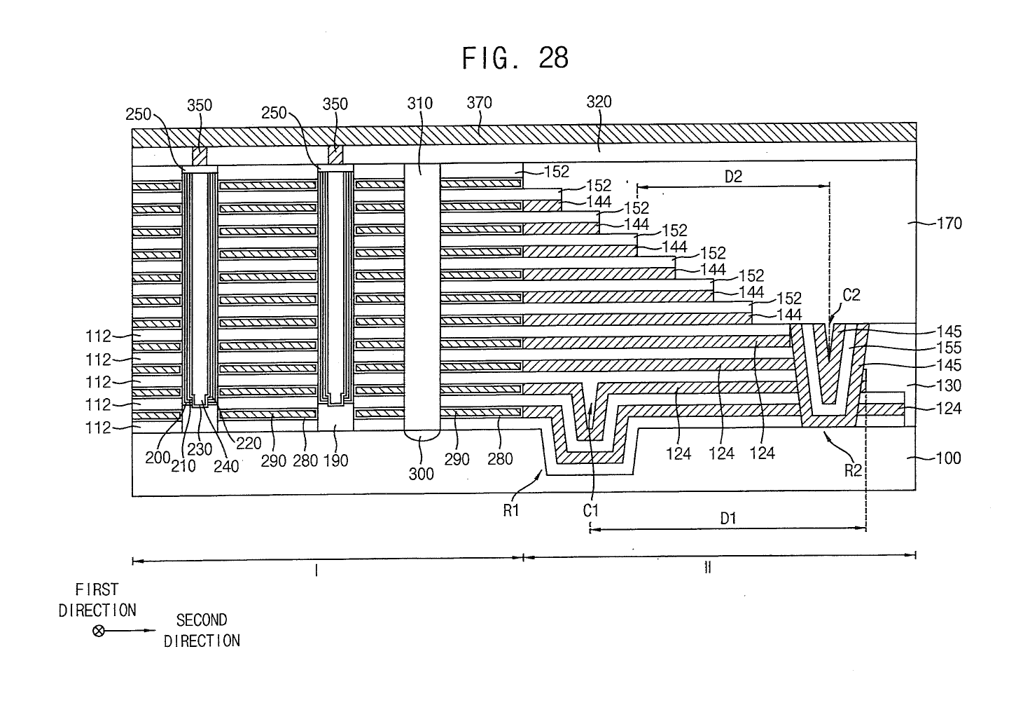

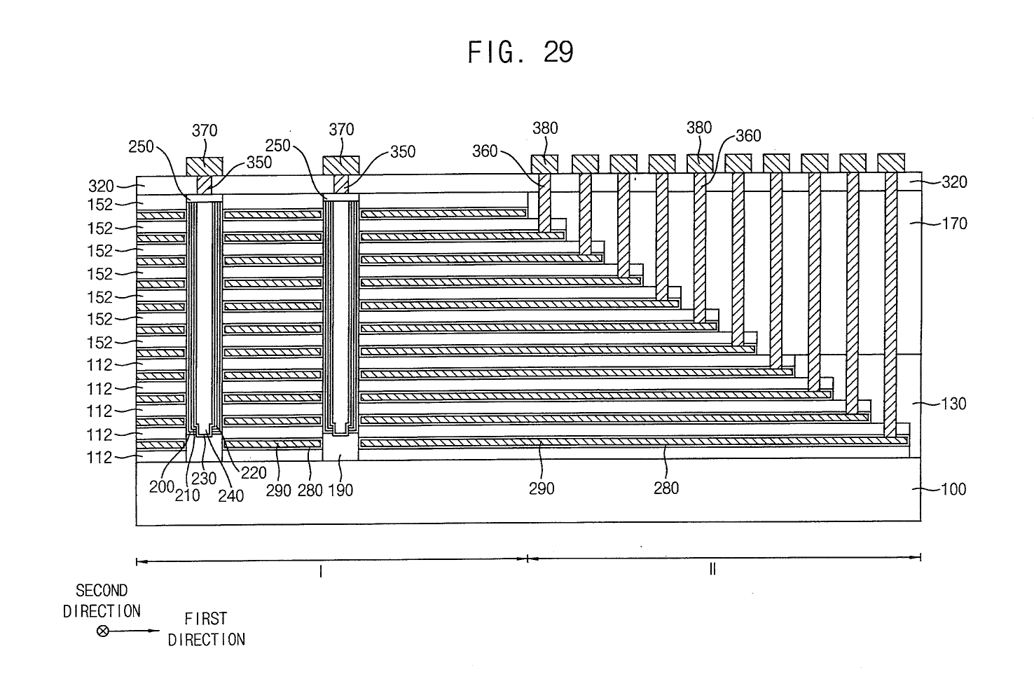

Referring to FIGS. 28 and 29, bit lines 370 that are electrically connected to the bit line contacts 350 and first wirings 380 that are electrically connected to the first contact plugs 360 may be formed to complete the vertical non-volatile memory device. The bit lines 370 and the first wirings 380 may include, for example, a metal, a metal nitride and/or doped polysilicon.

In example embodiments, the bit lines 370 may be spaced apart from each other along the first direction, and each bit line 370 may extend in the second direction. Additionally, in example embodiments, the first wirings 380 may be spaced apart from each other along the first direction, and each first wiring 380 may extend in the second direction. A second contact plug (not shown) and a second wiring (not shown) may be further formed on the first wiring 380.

Some elements of the vertical non-volatile memory device manufactured by the above processes may be described as follows.

The first and second conductive pads and the gate electrodes that may be integrally formed by the same process may form the conductive structures 290. The first and second conductive pads may extend from the gate electrodes, respectively, to be formed in the second region II. The first and second insulation pads 124 and 144 may extend from the conductive structures 290 that include the gate electrodes and the first and second conductive pads to be formed in the second region II.

Each first contact plug 360 may be electrically connected to either a first conductive pad or to a second conductive pad. The first reference structure R1 may be formed under at least one of the first and second insulation pads 124 and 144 in the second region II. The second reference structure R2 may contact at least one of the first and second insulation pads 124 and 144 in the second region II, and may be closer to the first region I than is an end portion of the lowermost one of the first and second insulation pads 124 and 144.

The first and second conductive pads may have lengths extending in the first direction that may gradually decrease from a bottom level to a top level, and the first and second insulation pads 124 and 144 may have lengths extending in the second direction that may gradually decrease from a bottom level to a top level.

As described above, in the method of manufacturing the vertical non-volatile memory device, the first reference structure R1 may be used to monitor the positions and/or sizes of the first insulation layer patterns 112 and the first sacrificial layer patterns 122 of the lower mold structure, and the second reference structure R2 may be used to monitor the positions and/or sizes of the second insulation layer patterns 152 and the second sacrificial layer patterns 142 of the upper mold structure. Thus, the alignment between the contact plugs 360 and the first and second conductive pads that are subsequently substituted for portions of the first and second sacrificial layer patterns 122 and 142 may be improved.

The first and second reference structures R1 and R2 may be formed in the cell region instead of in the peripheral circuit region, so that the vertical non-volatile memory device may have a high degree of integration while still including the first and second reference structures R1 and R2.

The first and second reference structures R1 and R2 may not be formed in a portion of the cell region in which the first and second conductive pads that contact the first contact plugs 360 are formed, and instead may only be formed in portions of the second region in which the first and second insulation pads 124 and 144 are formed. Thus, the first and second reference structures may not disrupt the operation of the vertical non-volatile memory device.

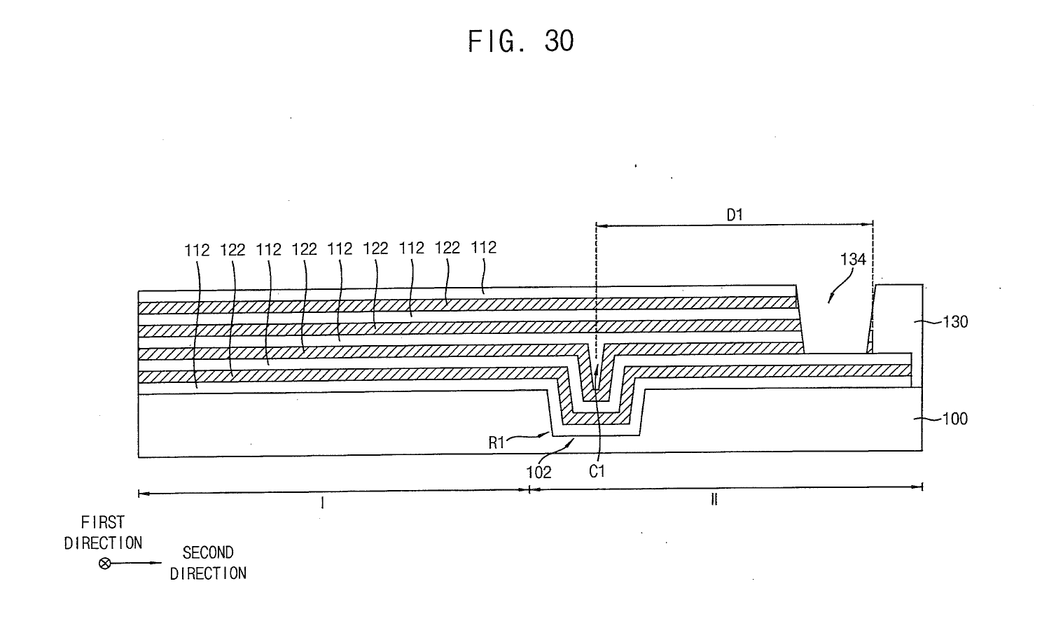

FIGS. 30 to 33 are cross-sectional views illustrating stages of a method of manufacturing a vertical non-volatile memory device in accordance with example embodiments. The method of manufacturing the vertical non-volatile memory device may include processes substantially the same as the method illustrated with reference to FIGS. 1 to 29, except for the position of the second reference structure. Thus, like reference numerals refer to like elements.

First, processes substantially the same as or similar to those illustrated with reference to FIGS. 1 to 9 may be performed.

Referring to FIG. 30, a process substantially the same as or similar to that illustrated with reference to FIGS. 10 and 11 may be performed. However, instead of forming the second trench 132 that exposes the top surface of the substrate 100 that is illustrated in FIGS. 10 and 11, a third trench 134 is formed that exposes a top surface of the first insulation layer pattern 112. In still other embodiments, the third trench 134 may be formed to expose a top surface of the first sacrificial layer pattern 122, or may be formed to expose a portion of the first insulation layer pattern 112 or the first sacrificial layer pattern 122 that is not the top surface thereof.

Thus, it will be appreciated that the present inventive concepts may include any type of third trench 134 that may be formed by removing at least a portion of the first insulation layer patterns 112 and the first sacrificial layer patterns 122.

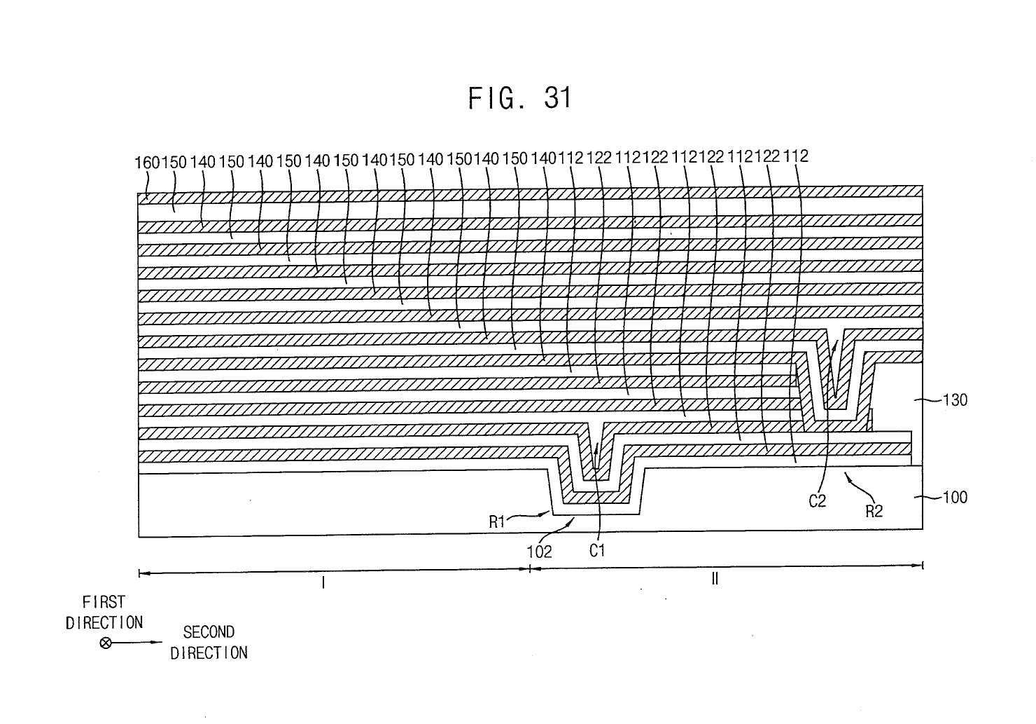

Referring to FIG. 31, a process substantially the same as or similar to that illustrated with reference to FIG. 12 may be performed. Thus, a plurality of second sacrificial layers 140 and a plurality of second insulation layers 150 may be alternately formed, and these layers may form a second reference structure R2 having a second center C2 in the third trench 134.

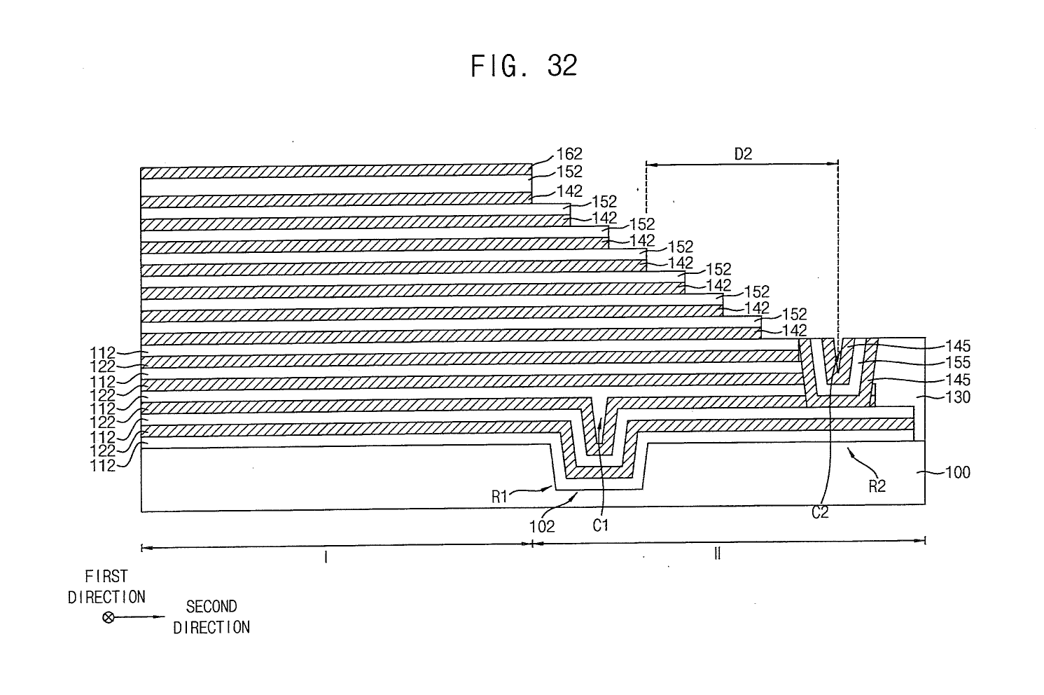

Referring to FIG. 32, a process substantially the same as or similar to that illustrated with reference to FIGS. 13 and 14 may be performed. Thus, second sacrificial layer patterns 142 and second insulation layer patterns 152 may be formed, and the positions and/or the sizes of the second sacrificial layer patterns 142 and the second insulation layer patterns 152 may be monitored using the second reference structure R2.

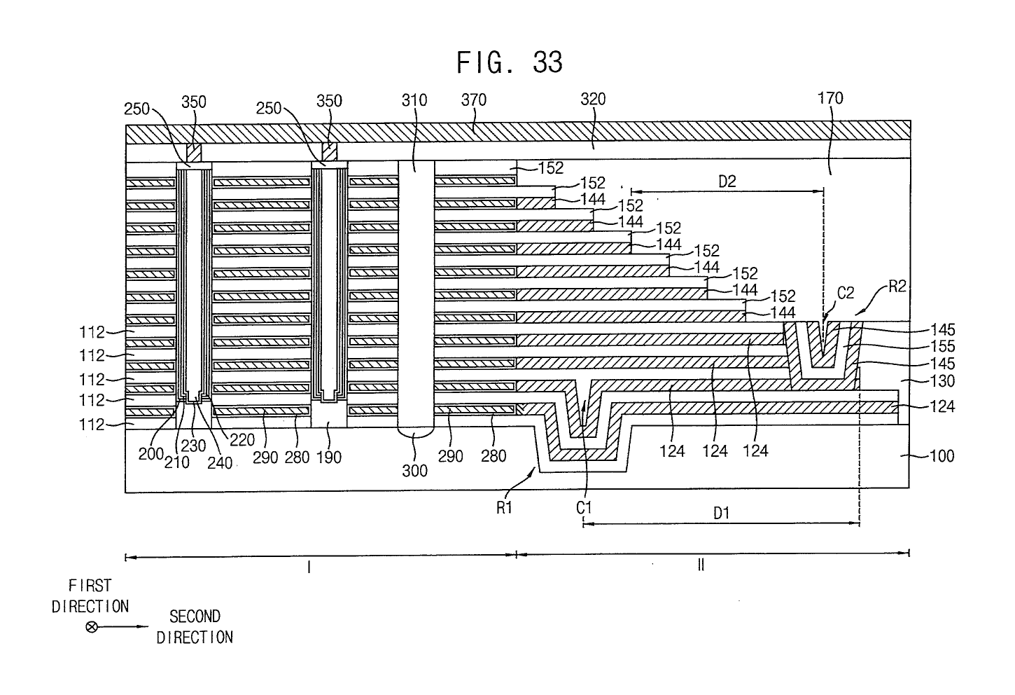

Referring to FIG. 33, processes substantially the same as or similar to those illustrated with reference to FIGS. 15 to 29 may be performed to complete the vertical non-volatile memory device.

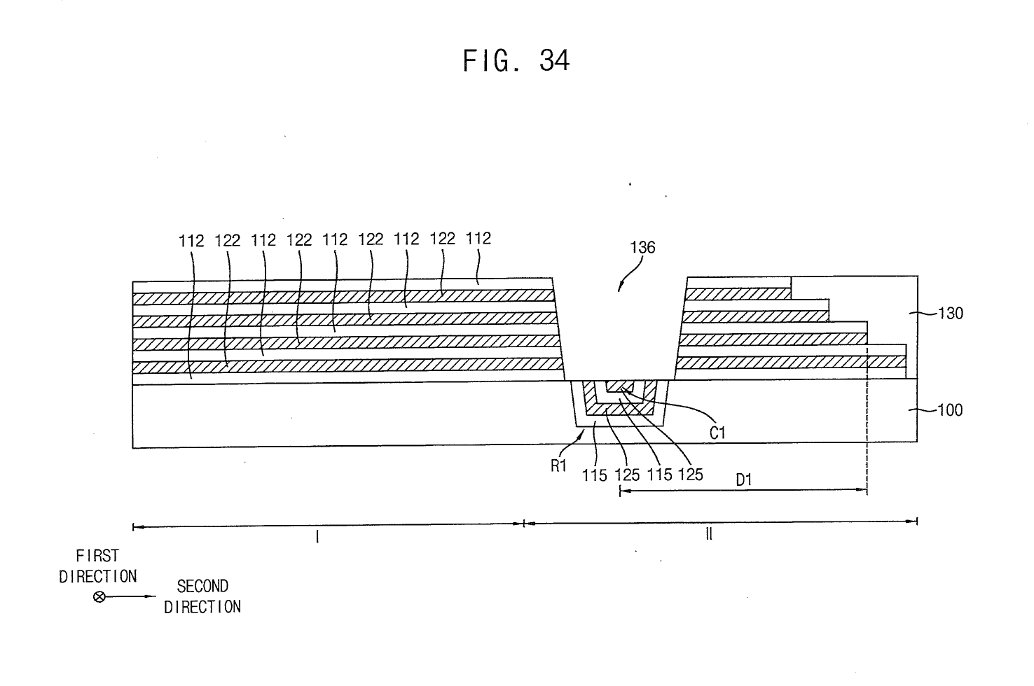

FIGS. 34 to 37 are cross-sectional views illustrating stages of a method of manufacturing a vertical non-volatile memory device in accordance with example embodiments. The method of manufacturing the vertical non-volatile memory device may include processes substantially the same as the method illustrated with reference to FIGS. 1 to 29, except for the position of the second reference structure. Thus, like reference numerals refer to like elements.

First, processes substantially the same as or similar to those illustrated with reference to FIGS. 1 to 9 may be performed.

Referring to FIG. 34, a process substantially the same as or similar to that illustrated with reference to FIGS. 10 and 11 may be performed. However, a fourth trench 136 that overlaps the first trench 102 may be formed instead of the second trench 132 that is more distant from the first region I than the first trench 102 is. Thus, the first reference structure R1 may be modified so as to include third insulation layer patterns 115 and third sacrificial layer patterns 125 in the first trench 102.

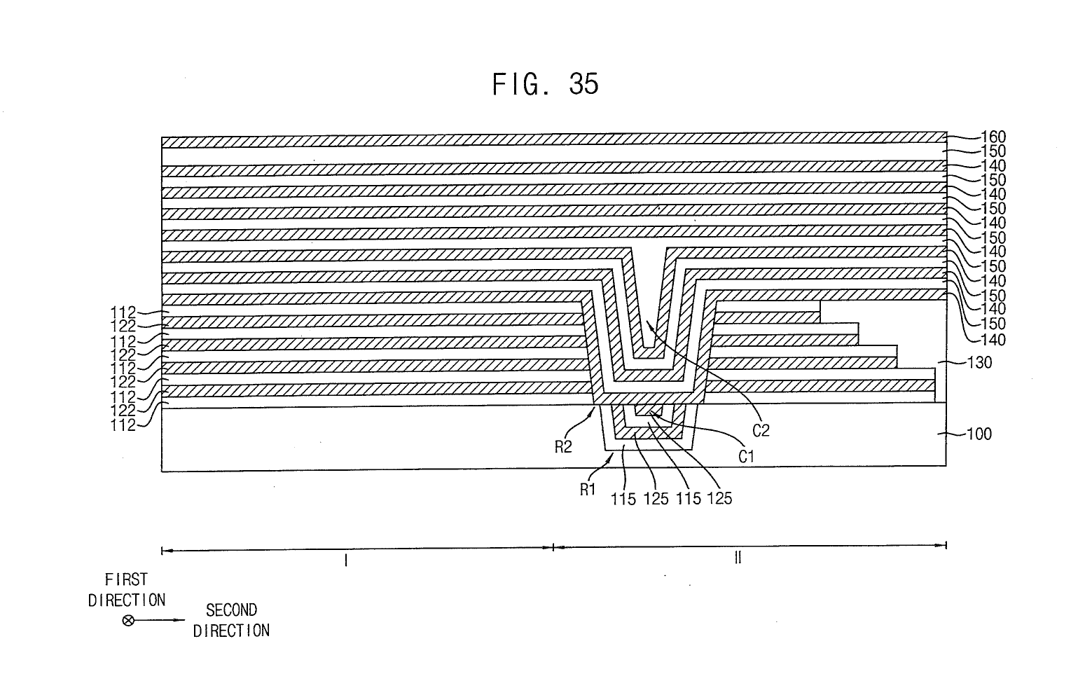

Referring to FIG. 35, a process substantially the same as or similar to that illustrated with reference to FIG. 12 may be performed. Thus, a second reference structure R2 having a second center C2 may be formed, and a plurality of second sacrificial layers 140 and a plurality of second insulation layers 150 may be alternately and repeatedly formed. The second reference structure R2 may be formed to vertically overlap the first reference structure R1. In some embodiments the first center C1 of the first reference structure R1 may be vertically aligned with the second center C2 of the second reference structure R2.

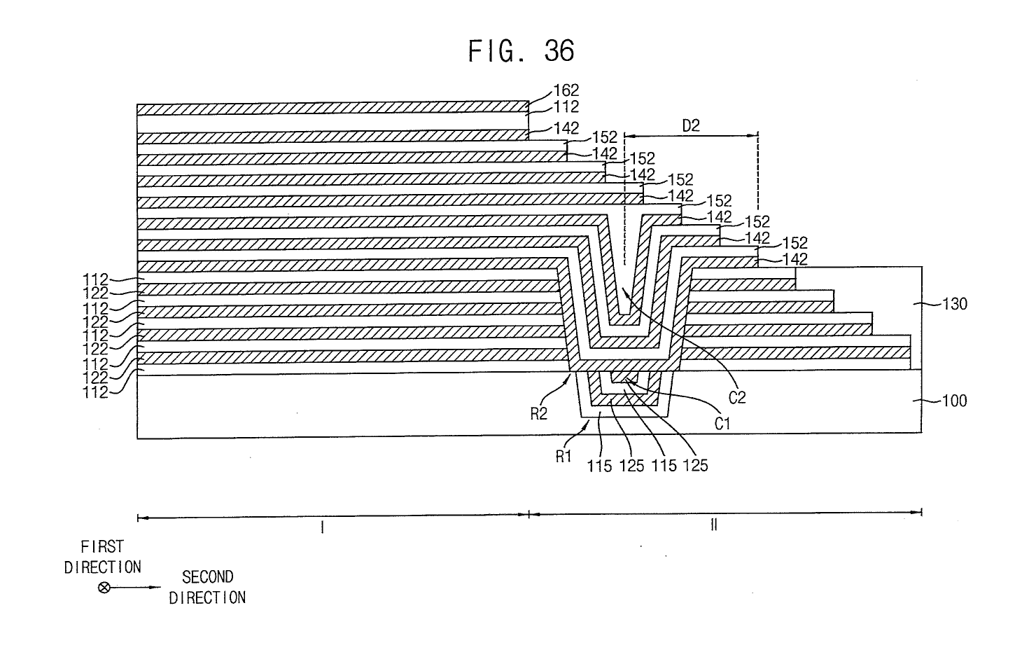

Referring to FIG. 36, a process substantially the same as or similar to that illustrated with reference to FIGS. 13 and 14 may be performed. Thus, second sacrificial layer patterns 142 and second insulation layer patterns 152 may be formed, and the positions and/or the sizes of the second sacrificial layer patterns 142 and the second insulation layer patterns 152 may be monitored using the second reference structure R2.

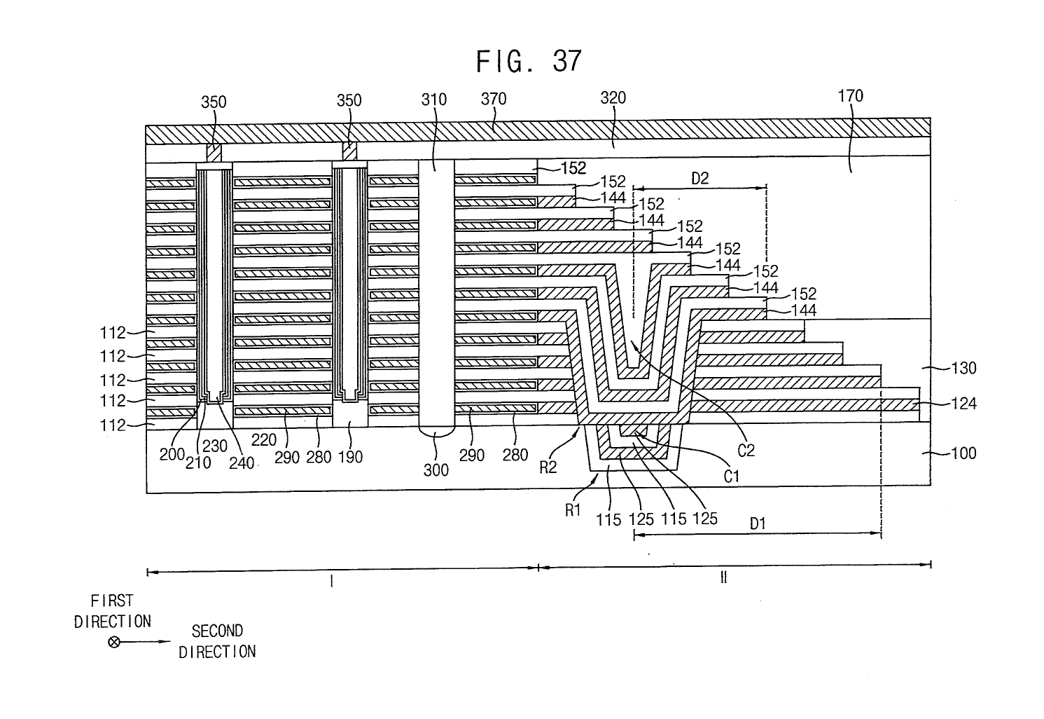

Referring to FIG. 37, processes substantially the same as or similar to those illustrated with reference to FIGS. 15 to 29 may be performed to complete the vertical non-volatile memory device.

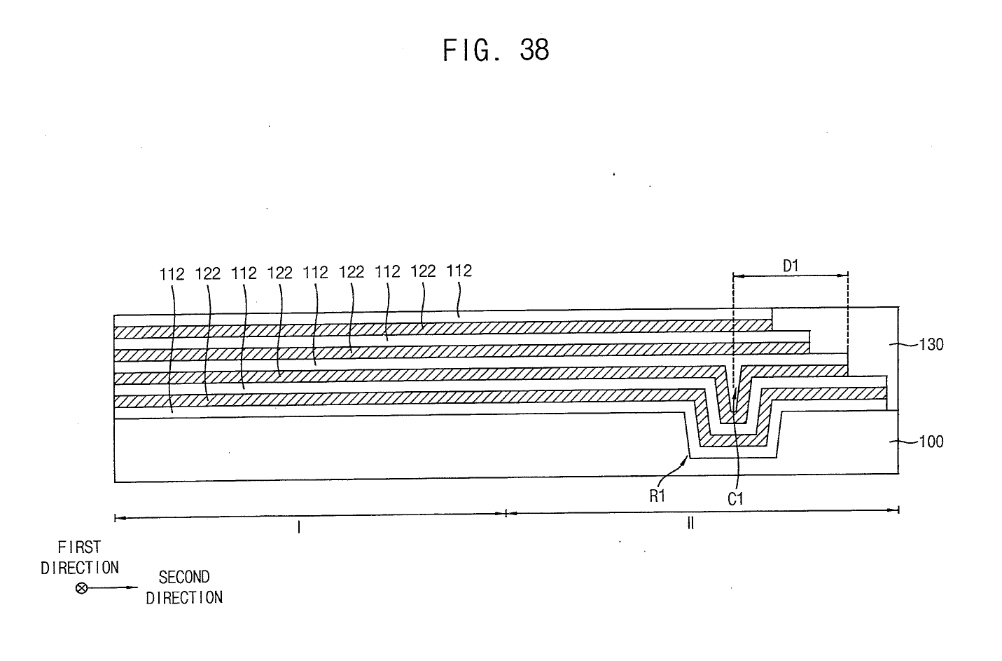

FIGS. 38 to 41 are cross-sectional views illustrating stages of a method of manufacturing a vertical non-volatile memory device in accordance with example embodiments. The method of manufacturing the vertical non-volatile memory device may include processes substantially the same as the method illustrated with reference to FIGS. 1 to 29, except for the positions of the first and second reference structures. Thus, like reference numerals refer to like elements.

Referring to FIG. 38, processes substantially the same as or similar to those illustrated with reference to FIGS. 1 to 9 may be performed.

However, the first reference structure R1 may not be formed to be adjacent the first region I, but may instead be formed at an edge portion of the second region II. Thus, the first reference structure R1 may be formed to be adjacent end portions of the first insulation layer patterns 112 and the first sacrificial layer patterns 122.

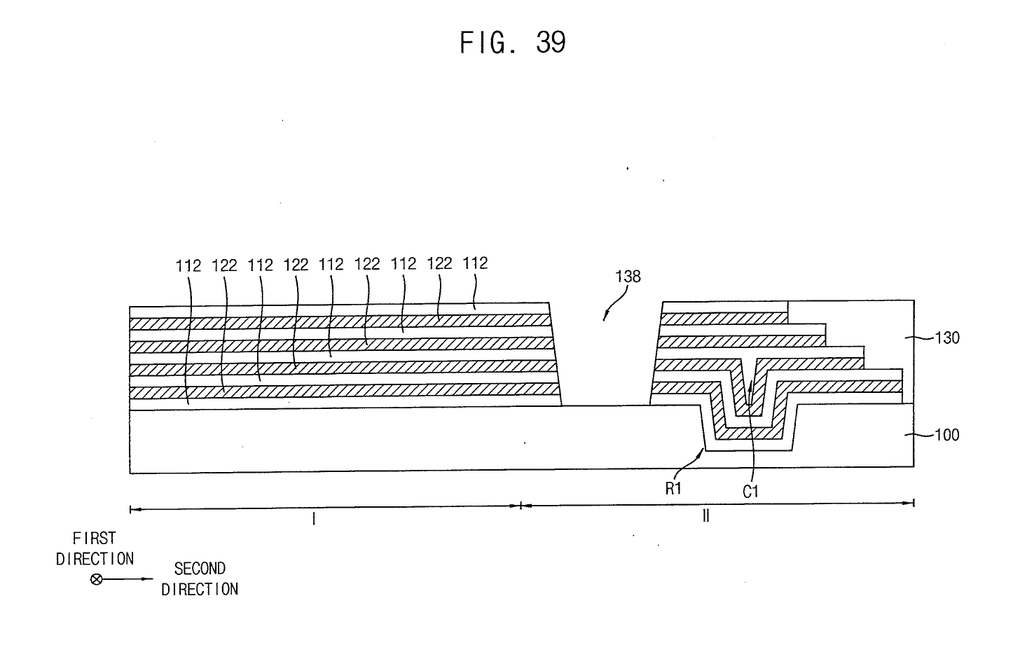

Referring to FIG. 39, a process substantially the same as or similar to that illustrated with reference to FIGS. 10 and 11 may be performed. However, a fifth trench 138 may be formed that is closer to the first region I in the second direction than is the first reference structure R1. The fifth trench 138 may be formed instead of the second trench 132.

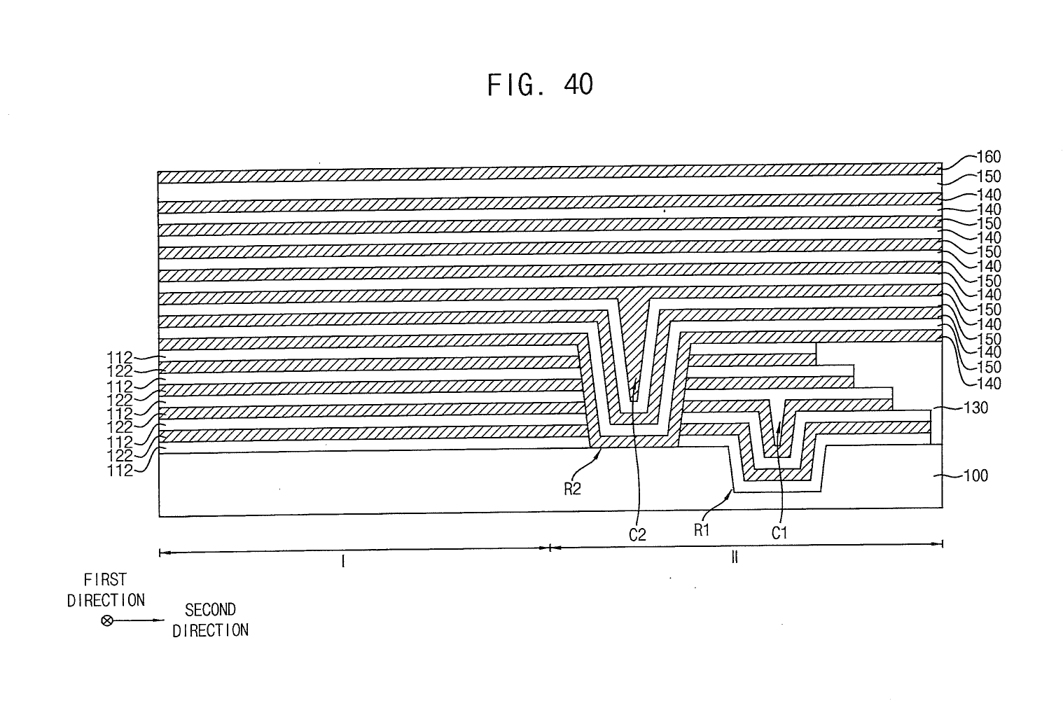

Referring to FIG. 40, a process substantially the same as or similar to that illustrated with reference to FIG. 12 may be performed. Thus, a second reference structure R2 having a second center C2 may be formed, and second sacrificial layers 140 and second insulation layers 150 may be alternately formed. The second reference structure R2 may be closer to the first region I than is the first reference structure R1.

A process substantially the same as or similar to that illustrated with reference to FIGS. 13 and 14 may be performed. Thus, second sacrificial layer patterns 142 and second insulation layer patterns 152 may be formed, and the positions and/or the sizes of the second sacrificial layer patterns 142 and the second insulation layer patterns 152 may be monitored using the second reference structure R2.

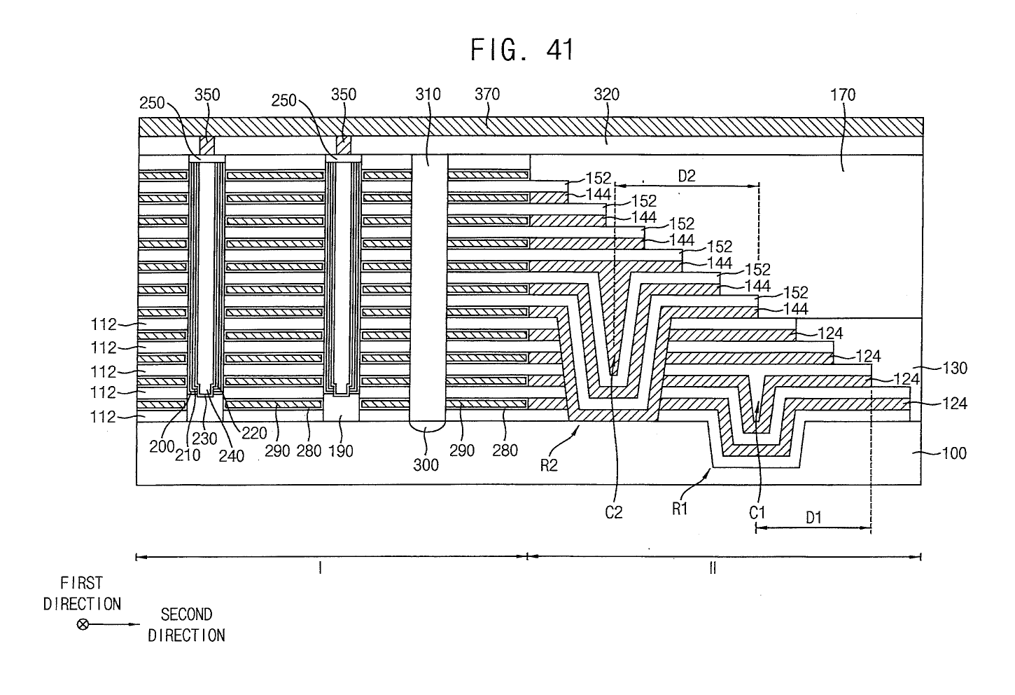

Referring to FIG. 41, processes substantially the same as or similar to those illustrated with reference to FIGS. 15 to 29 may be performed to complete the vertical non-volatile memory device.

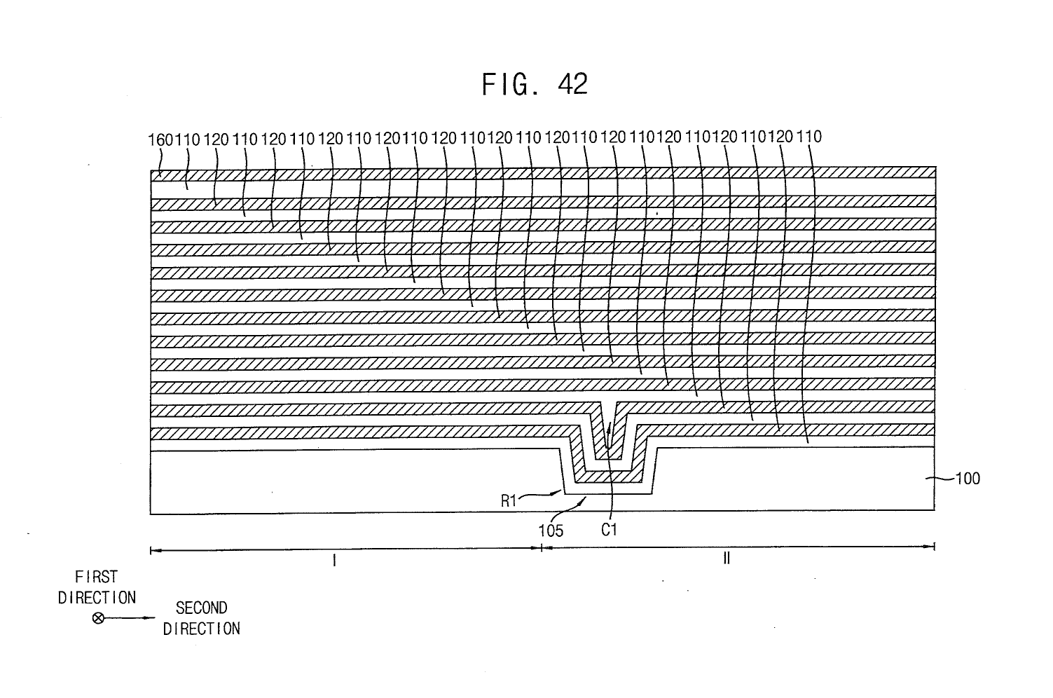

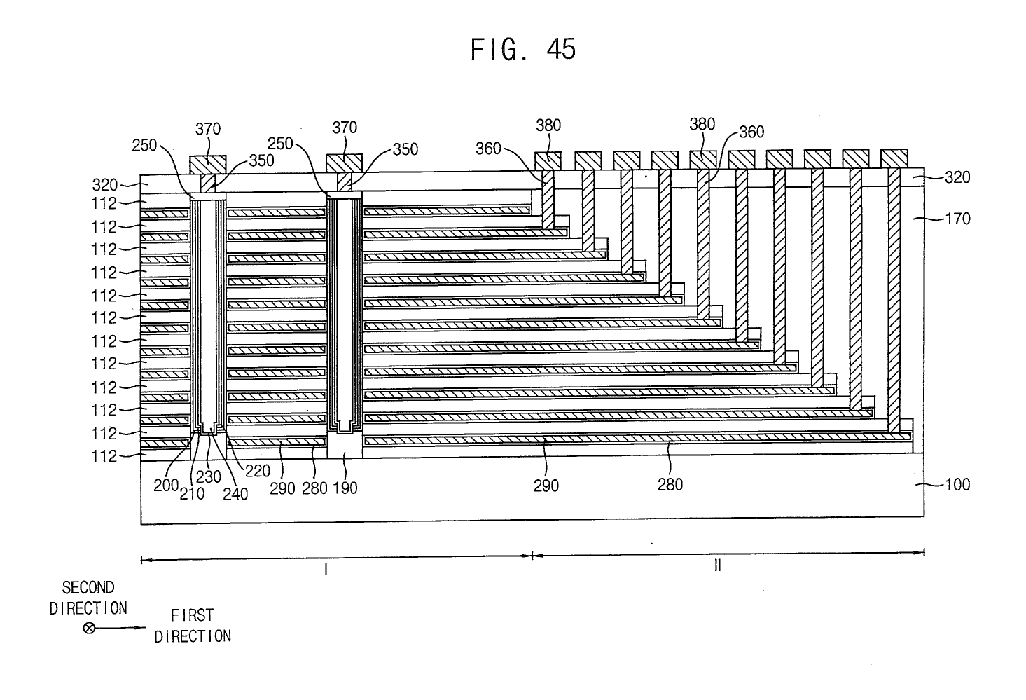

FIGS. 42 to 45 are cross-sectional views illustrating stages of a method of manufacturing a vertical non-volatile memory device in accordance with example embodiments. The method of manufacturing the vertical non-volatile memory device may include processes substantially the same as the method illustrated with reference to FIGS. 1 to 29, except that the second reference structure is not formed and the lower and upper mold structures are formed simultaneously. Thus, like reference numerals refer to like elements.

Referring to FIG. 42, processes substantially the same as or similar to those illustrated with reference to FIGS. 1 to 6 may be performed.

However, additional first insulation layers 110 and first sacrificial layers 120 may be alternately formed instead of the second insulation layers 140 and the second sacrificial layers 150. In other words, instead of having a lower mold structure and an upper mold structure, a lower mold structure is formed that has additional levels. A polish stop layer 160 may be further formed on an uppermost one of the first insulation layers 110.

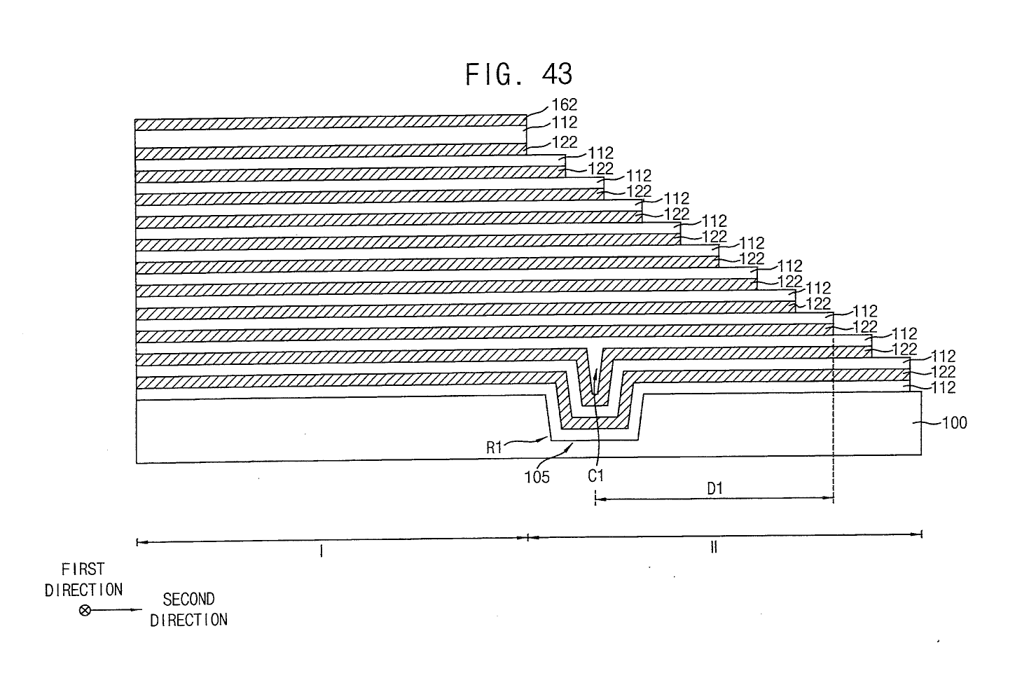

Referring to FIG. 43, a process substantially the same as or similar to that illustrated with reference to FIGS. 7 and 8 may be performed. Thus, first insulation layer patterns 112, first sacrificial layer patterns 122 and a polish stop layer pattern 162 may be formed, and the positions and/or sizes of the first insulation layer patterns 112 and the first sacrificial layer patterns 122 may be monitored using the first reference structure R1.

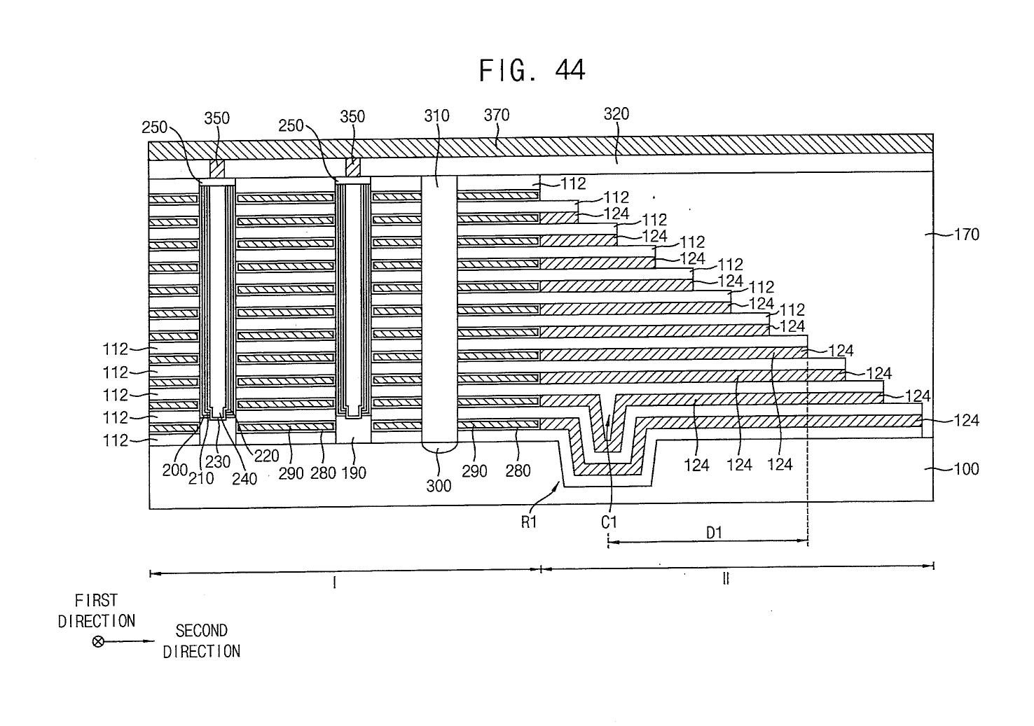

Referring to FIG. 44, processes substantially the same as or similar to those illustrated with reference to FIGS. 15 to 29 may be performed to complete the vertical non-volatile memory device.

While example embodiments have been particularly shown and described, it will be understood by one of ordinary skill in the art that variations in form and detail may be made therein without departing from the spirit and scope of the claims.

1. A vertical non-volatile memory device, comprising:
a substrate having a top surface that extends in both a first direction and in a second direction that is substantially perpendicular to the first direction, the substrate including a first region and a second region that surrounds the first region;
a plurality of gate electrodes that are stacked in the first region of the substrate in a third direction that is substantially perpendicular to both the first direction and the second direction;
a channel extending in the third direction through the gate electrodes;
conductive pads in the second region of the substrate, a respective one of the conductive pads extending from the respective gate electrodes in the first direction;
insulation pads in the second region of the substrate, a respective one of the insulation pads extending from the respective gate electrodes in the second direction;
a plurality of contact plugs, a respective one of which is electrically connected to the respective conductive pads; and
a first reference structure under at least one of the insulation pads in the second region of the substrate.

2. The device of claim 1, wherein the first reference structure extends in the first direction.

3. The device of claim 1, wherein the first region has a rectangular shape when viewed from above, and the first reference structure is in a portion of the second region that is adjacent to the first region along the second direction.

4. The device of claim 1, wherein a plurality of additional first reference structures are in the second region of the substrate, wherein each of the plurality of additional first reference structures extends in the first direction.

5. The device of claim 1, wherein the first reference structure includes:
a trench in the second region of the substrate; and
a portion of at least one of the insulation pads that has a generally concave shape.

6. The device of claim 1, wherein the conductive pads are stacked on the substrate in levels from a bottom level that is closest to the substrate to a top level that is farthest from the substrate, and wherein the lengths of the conductive pads in the first direction decrease from the bottom level to the top level, and wherein the insulation pads are stacked on the substrate in levels from a bottommost level that is closest to the substrate to a topmost level that is farthest from the substrate, and wherein the lengths of the insulation pads in the second direction decrease from the bottommost level to the topmost level.

7. The device of claim 6, further comprising a second reference structure in the second region of the substrate, wherein the second reference structure contacts at least some of the insulation pads and is closer to the first region than is an end portion of a lowermost one of the insulation pads.

8. The device of claim 7, wherein the second reference structure extends in the first direction.

9. The device of claim 7, wherein the second reference structure includes a material substantially the same as that of the insulation pads, and includes at least one layer having a concave shape.

10. The device of claim 1, wherein the conductive pad includes a material that is substantially the same as a material of the gate electrodes.

11. The device of claim 1, further comprising a tunnel insulation layer pattern, a charge storage layer pattern and a blocking layer pattern between the channel and each of the gate electrodes.

12-15. (canceled)

16. A vertical non-volatile memory device, comprising:
a substrate having a top surface that extends in both a first direction and in a second direction that is substantially perpendicular to the first direction, the substrate further including a bottom surface that is spaced apart from the top surface in a third direction, the third direction being substantially perpendicular to both the first direction and the second direction;
a plurality of gate electrodes that are stacked on the substrate in the third direction;
a channel extending in the third direction through the gate electrodes;
a plurality of conductive pads that are stacked on the substrate in the third direction, a respective one of the conductive pads extending from the respective gate electrodes in the first direction;
a plurality of insulation pads, a respective one of which extends from respective ones of the gate electrodes in the second direction;
a plurality of contact plugs, a respective one of which extends in the third direction to electrically connect to respective ones of conductive pads; and
a first reference structure under at least one of the insulation pads, the first reference structure comprising a trench that includes at least one material layer that includes a concave portion that is in the trench.

17. The device of claim 16, wherein the at least one material layer comprises one of the insulation pads.

18. The device of claim 16, wherein the material layer comprises one of the insulation pads and a concave portion of a sacrificial layer.

19. The device of claim 16, wherein the first reference structure extends in the first direction.

20. The device of claim 16, wherein the conductive pads are stacked on the substrate in levels from a bottom level that is closest to the substrate to a top level that is farthest from the substrate, and wherein the lengths of the conductive pads in the first direction decrease from the bottom level to the top level, and wherein the insulation pads are stacked on the substrate in levels from a bottommost level that is closest to the substrate to a topmost level that is farthest from the substrate, and wherein the lengths of the insulation pads in the second direction decrease from the bottommost level to the topmost level.

21. The device of claim 20, further comprising a second reference structure under at least one of the insulation pads, the second reference structure comprising a concave portion of one of the insulation pads.

22. The device of claim 21, wherein the second reference structure is closer to the gate electrodes than is an end portion of a lowermost one of the insulation pads.

23. The device of claim 21, wherein the second reference structure extends in the first direction.

24. The device of claim 21, wherein the second reference structure overlaps the first reference structure along an axis that extends in the third direction.
